(19) United States
(12) Patent Application Publication
(10) Pub. No.: US 2019/0004661 A1
(43) Pub. Date: Jan. 3, 2019

(54) ELECTRONIC DEVICE FOR PROVIDING SERVICE AND OPERATING METHOD THEREOF

(71) Applicant: Samsung Electronics Co., Ltd., Suwon-si (KR)

(72) Inventors: Keunsik LEE, Hwaseong-si (KR); Kihuk LEE, Suwon-si (KR)

(21) Appl. No.: 16/018,543

(22) Filed: Jun. 26, 2018

(30) Foreign Application Priority Data
Jun. 30, 2017 (KR) 10-2017-0083565

(51) Int. Cl. G06F 3/041; G01R 31/28; G06F 3/044

(52) U.S. Cl. CPC G06F 3/0414; G06F 3/044; G01R 31/2891; G06F 3/0418

(57) ABSTRACT

An electronic device and an operating method are provided. The electronic device includes a housing including a first plate and a second plate facing in a direction opposite of the first plate, a touch screen display disposed in the housing and including a first surface exposed through a part of the first plate and a second surface facing a direction of the second plate, a pressure sensing circuit attached to the second surface via an adhesive layer, disposed between the first plate and the second plate, and configured to detect a pressure on a first region of the touch screen display by an external force, a wireless communication circuit disposed in the housing, a memory disposed in the housing, and at least one processor disposed in the housing and electrically connected with the touch screen display, the pressure sensing circuit, the wireless communication circuit, and the memory, wherein the memory stores instructions that, when executed by the at least one processor, cause the at least one processor to detect the pressure on the first region of the touch screen display using the pressure sensing circuit and to perform an operation associated with the electronic device in response to the detected pressure, when an abnormal operation of the pressure sensing circuit is not detected, and to detect a touch on the first region using the touch screen display and to perform the operation associated with the electronic device in response to the detected touch, when the abnormal operation of the pressure sensing circuit is detected. Other embodiments may be possible.

### CROSS-REFERENCE TO RELATED APPLICATION(S)

This application is based on and claims priority under 35 U.S.C. § 119(a) of a Korean patent application number 10-2017-0083565, filed on Jun. 30, 2017, in the Korean Intellectual Property Office, the disclosure of which is incorporated by reference herein in its entirety.

### BACKGROUND

### 1. Field

The disclosure relates to an electronic device for providing services and an operating method thereof.

### 2. Description of Related Art

The above information is presented as background information only to assist with an understanding of the disclosure. No determination has been made, and no assertion is made, as to whether any of the above might be applicable as prior art with regard to the disclosure.

As the use of multimedia services using electronic devices increases, the amount of information to be processed and the amount of information to be displayed in the electronic devices are increasing. There is an increasing use of electronic devices with touch screens that can improve space utilization and increase the size of the display.

The electronic device detects a user's touch input through a touch screen and displays a control command execution result on the touch screen while performing a control command according to the touch input. The electronic device can provide only limited services by performing a control command corresponding to the touch input detected through the touch screen. Recently, the electronic device further includes a pressure sensor to consider a pressure input together with the touch input, thereby providing various services.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an apparatus and method for a situation that may occur in which the pressure sensor provided in the electronic device operates abnormally. For example, an abnormality may occur in the adhesion state of the pressure sensor due to an external impact applied to the electronic device, so that the pressure sensor may not be able to sense the pressure input applied to the display. When the pressure sensor operates abnormally in the electronic device, it cannot provide various services corresponding to the pressure input.

Additional aspects will be set forth in part in the description which follows and, in part, will be apparent from the description, or may be learned by practice of the presented embodiments.

In accordance with an aspect of the disclosure, a method and device for detecting whether an abnormal operation (or abnormal behavior) of a pressure sensor in an electronic device are provided.

In accordance with an aspect of the disclosure, a method and device are provided. The method includes services corresponding to a pressure input using a touch input when a pressure sensor operates abnormally in an electronic device.

In accordance with an aspect of the disclosure, an electronic device is provided. The electronic device includes a housing including a first plate and a second plate facing in a direction opposite of the first plate, a touch screen display disposed in the housing and including a first surface exposed through a part of the first plate and a second surface facing a direction of the second plate, a pressure sensing circuit attached to the second surface via an adhesive layer, disposed between the first plate and the second plate, and configured to detect a pressure on a first region of the touch screen display by an external force, a wireless communication circuit disposed in the housing, a memory disposed in the housing, and at least one processor disposed in the housing and electrically connected with the touch screen display, the pressure sensing circuit, the wireless communication circuit, and the memory, wherein the memory stores instructions that, when executed by the at least one processor, cause the at least one processor to detect the pressure on the first region of the touch screen display using the pressure sensing circuit and to perform an operation associated with the electronic device in response to the detected pressure, when an abnormal operation of the pressure sensing circuit is not detected, and to detect a touch on the first region using the touch screen display and to perform the operation associated with the electronic device in response to the detected touch, when the abnormal operation of the pressure sensing circuit is detected.

In accordance with another aspect of the disclosure, an operating method of an electronic device is provided. The operating method includes detecting an abnormal operation of a pressure sensing circuit, performing an operation associated with the electronic device in response to a pressure to a first region of a display using the pressure sensing circuit when the abnormal operation of the pressure sensing circuit is not detected, and performing the operation associated with the electronic device in response to a touch on the first region using the touch screen display when the abnormal operation of the pressure sensing circuit is detected.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective diagram illustrating an electronic device according to various embodiments of the disclosure;

FIG. 2 illustrates an electronic device in a network environment according to various embodiments of the disclosure;

FIG. 3 is a block diagram illustrating the relationship between some of the components included in an electronic device according to various embodiments of the disclosure;

FIGS. 4A, 4B, 4C, 4D, 4E and 4F illustrate circuit configurations of a pressure sensor according to various embodiments of the disclosure;

FIG. 5A is a perspective diagram illustrating an electronic device including a capacitive pressure sensor according to various embodiments of the disclosure;

FIG. 5B is a cross-sectional diagram illustrating an electronic device including a capacitive pressure sensor according to various embodiments of the disclosure;

FIGS. 6A and 6B are perspective diagrams illustrating a pressure sensor according to various embodiments of the disclosure;

FIG. 7 is a perspective diagram illustrating an electronic device showing the position of a pressure sensor according to various embodiments of the disclosure;

FIG. 8 is a block diagram illustrating an electronic device according to various embodiments of the disclosure;

FIG. 9 is a block diagram illustrating a program module according to various embodiments of the disclosure;

FIG. 10 is a block diagram illustrating a sensor IC and a program module representing a transmission path of touch data and pressure data according to various embodiments of the disclosure;

FIG. 11 is a block diagram illustrating a program module for resolution change in an electronic device according to various embodiments of the disclosure;

FIG. 12 illustrates an operational procedure according to whether a pressure sensor operates normally in an electronic device according to various embodiments of the disclosure;

FIG. 13 illustrates an operational procedure for detecting whether a pressure sensor operates normally in an electronic device according to various embodiments of the disclosure;

FIG. 14 illustrates an operational procedure for detecting whether a pressure sensor operates normally in an electronic device according to various embodiments of the disclosure;

FIG. 15 illustrates an operational procedure for detecting a touch input for triggering an event corresponding to a pressure input in an electronic device according to various embodiments of the disclosure;

FIGS. 16A and 16B illustrate screen configurations changed when an abnormal operation of a pressure sensor is detected in an electronic device according to various embodiments of the disclosure;

FIG. 17 illustrates an operational procedure for detecting a touch input for triggering an event corresponding to a pressure input in an electronic device according to various embodiments of the disclosure; and

FIG. 18 illustrates a screen configuration changed when an abnormal operation of a pressure sensor is detected in an electronic device according to various embodiments of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, each of such phrases as “A or B” or “at least one of A and/or B” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly or via another element (e.g., a third element).

The term “configured (or set) to . . . ” used in the disclosure may be interchangeably used with the terms “suitable for . . . ,” “having the capacity to . . . ,” “designed to . . . ,” “adapted to . . . ,” “made to . . . ,” or “capable of . . . ” in a hardware or software level depending on the situation. In a certain situation, the term “a device configured to . . . ” may refer to “the device being capable of . . . ” with another device or parts. For example, “a processor configured (set) to perform A, B, and C” may refer, for example, and without limitation, to a dedicated processor (for example, an embedded processor) for performing a corresponding operation, or a generic-purpose processor (for example, a central processing unit (CPU) or an application processor (AP)), or the like, for performing corresponding operations by executing one or more software programs stored in a memory device.

An electronic device according to various embodiments of the disclosure may include at least one of smartphones, tablet personal computers (PCs), mobile phones, video telephones, electronic book readers, desktop PCs, laptop PCs, netbook computers, workstations, servers, PDAs, portable multimedia players (PMPs), motion picture experts group (MPEG-1 or MPEG-2) audio layer 3 (MP3) players, medical devices, cameras, or wearable devices, or the like, but is not limited thereto. The wearable devices may include at least one of accessories (for example, watches, rings, bracelets, ankle bracelets, necklaces, glasses, contact lenses, head-mounted-devices (HMDs), etc.), fabric- or clothing-mounted devices (for example, electronic apparels), body-mounted devices (for example, skin pads, tattoos, etc.), bio-implantable circuits, or the like, but are not limited thereto.

According to embodiments, the electronic devices may include at least one of, for example, televisions (TVs), digital versatile disc (DVD) players, audios, refrigerators, air conditioners, cleaners, ovens, microwave ovens, washing machines, air cleaners, set-top boxes, home automation control panels, security control panels, media boxes (for example, Samsung HomeSync™, Apple TV™, or Google TV™), game consoles (for example, Xbox™ and PlayStation™), electronic dictionaries, electronic keys, camcorders, electronic picture frames, or the like, but are not limited thereto.

According to another embodiment, the electronic devices may include at least one of medical devices (for example, various portable medical measurement devices (for example, a blood glucose monitoring device, a heartbeat measuring device, a blood pressure measuring device, a body temperature measuring device, and the like), a magnetic resonance angiography (MRA), a magnetic resonance imaging (MRI), a computed tomography (CT), scanners, and ultrasonic devices), navigation devices, global navigation satellite systems (GNSS), event data recorders (EDRs), flight data recorders (FDRs), vehicle infotainment devices, electronic equipment for vessels (for example, navigation systems and gyrocompasses), avionics, security devices, head units for vehicles, industrial or home robots, drones, automatic teller's machines (ATMs) of financial institutions, points of sales (POSs) of stores, or internet of things (for example, light bulbs, various sensors, sprinkler devices, fire alarms, thermostats, street lamps, toasters, exercise equipment, hot water tanks, heaters, boilers, and the like), or the like, but are not limited thereto.

According to an example embodiment, the electronic devices may include at least one of furniture, a part of buildings/structures or cars, electronic boards, electronic signature receiving devices, projectors, or various measuring instruments (for example, water meters, electricity meters, gas meters, or wave meters, and the like), or the like, but are not limited thereto. The electronic devices according to various embodiments may be flexible or may be a combination of two or more devices of the above-mentioned devices. Also, electronic devices according to various embodiments of the disclosure are not limited to the above-mentioned devices. In the disclosure, the term “user” may refer to a person who uses the electronic device or a device that uses the electronic device (for example, an artificial intelligence electronic device).

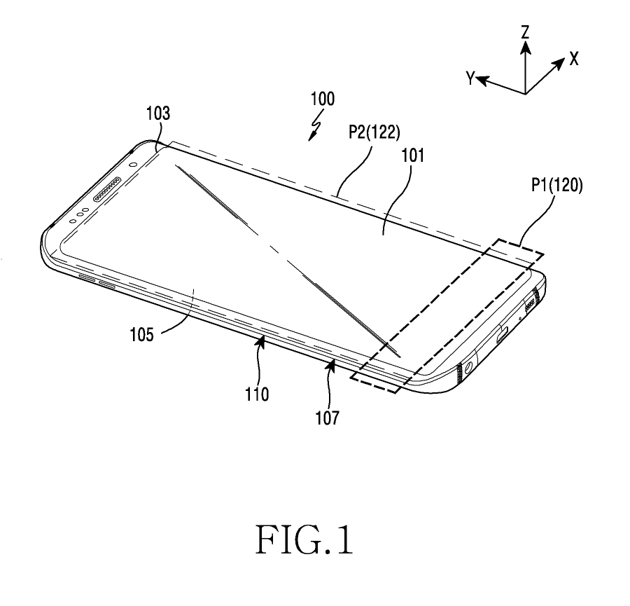

FIG. 1 is a perspective diagram illustrating an electronic device according to various embodiments of the disclosure.

Referring to FIG. 1, an electronic device 100 may include a housing 107. According to one embodiment, the housing 107 may be made of a conductive member and/or a non-conductive member. According to one embodiment, the housing 107 may include a first plate 103, a second plate 105 facing in a direction opposite that of the first plate 103, and a side member 110 arranged in such a manner as to surround a space between the first plate 103 and the second plate 105. According to one embodiment, the first plate 103 may include a cover window and the second plate 105 may include a rear cover. According to one embodiment, the side member 110 may be formed integrally with the second plate 105. According to one embodiment, the side member 110 may be arranged in such a manner that it is engaged with the second plate 105.

According to various embodiments, the electronic device 100 may include a touch screen display 101 that is arranged in such a manner as to be exposed to at least a partial region of the first plate 103. For example, at least a partial region of a first surface of the touch screen display 101 may be exposed to the outside through the at least a partial region of the first plate 103. According to one embodiment, at least a partial region of a second surface of the touch screen display 101 may be attached to a pressure sensor. The pressure sensor may be arranged between the first plate 103 and the second plate 105, and the first surface of the pressure sensor may be attached to the second surface of the touch screen display 101 through an adhesive layer. According to various embodiments, the pressure sensor may be arranged in a P1 region 120 or a P2 region 122 of the illustrated electronic device 100. The P1 region 120 or the P2 region 122 is illustrative and the arrangement region of the pressure sensor may be another region overlapping at least a partial region of the region of the touch screen display 101.

According to various embodiments, in the touch screen display 101, substantially all of the first plate 103 of the electronic device 100 and a partial region of the second plate 105 including a partial region of the side member 110 or the side member 110 may be arranged to be defined as a display region.

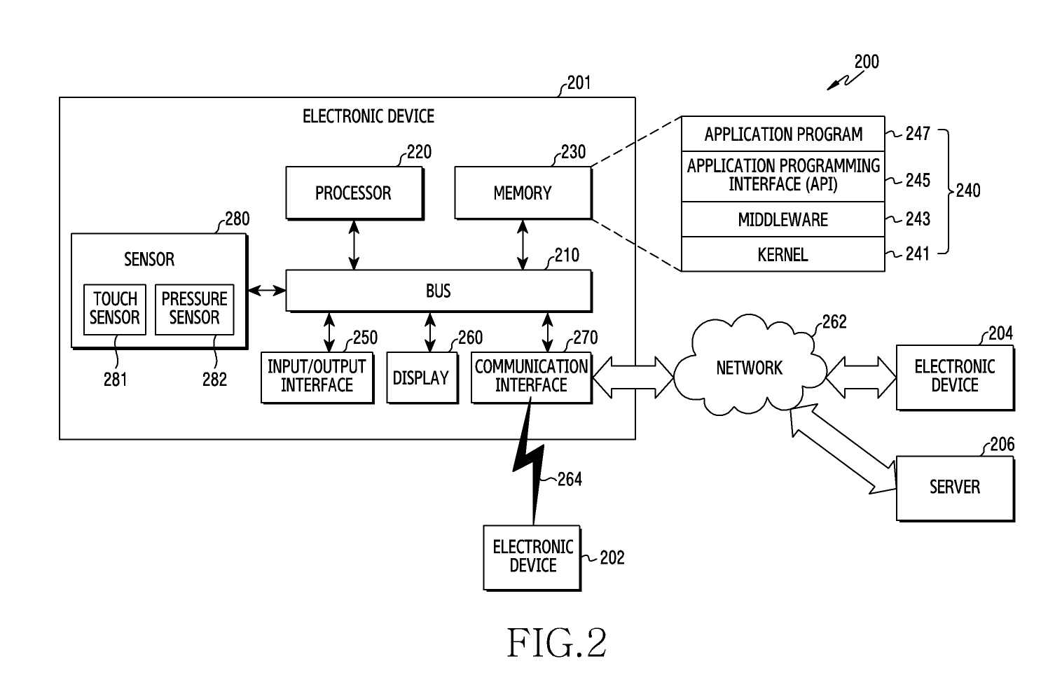

FIG. 2 illustrates an electronic device 201 in a network environment 200 according to various embodiments of the disclosure. An electronic device 201 of FIG. 2 may be the electronic device 100 illustrated in FIG. 1.

Referring to FIG. 2, the electronic device 201 may include a bus 210, a processor 220, a memory 230, an input/output interface 250, a display 260, a communication interface 270, and a sensor 280. In some embodiments, the electronic device 201 may omit at least one of the components or may additionally include other components.

The bus 210 may include a circuit that interconnects the components 220 to 280 and transfers communication (e.g., control messages or data) between the components.

The processor 220 may include one or more of a CPU, an AP, an image signal processor (ISP), and a communication processor (CP). The processor 120 may, for example, perform an operation or data processing on control and/or communication of at least one other component of the electronic device 201.

According to various embodiments, the processor 220 may determine whether a pressure sensor 282 operates normally. Whether the pressure sensor 282 operates normally may be determined based on whether the pressure sensor 282 is in a state capable of detecting the pressure applied to the display 260.

According to one embodiment, the processor 220 may determine whether the pressure sensor 282 operates normally based on whether the pressure (e.g., intensity of the touch input) due to a touch input is detected. For example, when a touch input to the display 260 is detected through a touch sensor 281, the processor 220 may determine whether the pressure sensor 282 operates normally based on whether the pressure applied to the display 260 due to the touch input is detected through the pressure sensor 282. When the touch input is detected through the touch sensor 281 but the pressure due to the touch input is not detected through the pressure sensor 282, the processor 220 may determine that the pressure sensor 282 operates abnormally. When the touch input is detected through the touch sensor 281 and significantly less pressure (e.g., a pressure value substantially close to zero) due to the touch input is detected through the pressure sensor 282, the processor 220 may determine that the pressure sensor 282 operates abnormally. When the touch input is detected through the touch sensor 281 and pressure (e.g., pressure greater than the significantly less pressure) due to the touch input is detected through the pressure sensor 282, the processor 220 may determine whether the pressure sensor 282 operates normally based on a pressure value (or pressure data) indicating the detected pressure. For example, when the detected pressure value is within a predetermined effective range (e.g., the detected pressure value>0), the processor 220 may determine that the pressure sensor 282 operates normally. When the detected pressure value is not within the predetermined effective range (e.g., the detected pressure value≤0), the processor 220 may determine whether the pressure sensor 282 operates abnormally. The pressure value may be obtained based on at least one of a capacitance change amount, a current change amount, a resistance change amount, and a voltage change amount. For example, when the pressure sensor 282 is a capacitive pressure sensor, the pressure value can be obtained based on the capacitance change amount. When the pressure sensor 282 is an inductive pressure sensor, the pressure value can be obtained based on the current change amount. When the pressure sensor 282 is a strain gauge pressure sensor, the pressure value can be obtained based on the resistance change amount. When the pressure sensor 282 is a piezo pressure sensor, the pressure value can be obtained based on the current change amount or the voltage change amount. The above-described methods are illustrative, and when the pressure sensor 282 is driven in a method other than the above-described methods, the pressure value can be obtained based on another value.

According to one embodiment, the processor 220 may determine whether the pressure sensor 282 operates normally based on a parasitic capacitance value associated with the pressure sensor 282. The parasitic capacitance value may refer to a capacitance value generated in an adhesive layer between the pressure sensor 282 and the display 260 (e.g., the touch screen display 101). According to one embodiment, the adhesive layer between the pressure sensor 282 and the display 260 may include a dielectric layer positioned between an auxiliary material layer (e.g., Cu sheet or Cu & Gr sheet) disposed between the pressure sensor 282 and the display 260 and an electrode body layer of the pressure sensor 282. According to one embodiment, the adhesive layer between the pressure sensor 282 and the display 260 may include an adhesive member for attaching the pressure sensor 282 and the auxiliary material layer. The parasitic capacitance value may be maintained at a constant value when the pressure sensor 282 is normally attached to the display 260, but may be changed to a different value when the pressure sensor 282 is detached from the display 260. According to various embodiments of the present document, the processor 220 may determine whether the pressure sensor 282 operates normally using the above-described characteristics of the parasitic capacitance. For example, the processor 220 may measure a parasitic capacitance generated in the adhesive layer between the pressure sensor 282 and the display 260, and may compare the measured parasitic capacitance with a predetermined reference capacitance. The processor 220 may determine that the pressure sensor 282 operates normally when the measured parasitic capacitance is equal to the reference capacitance. When the measured parasitic capacitance is not equal to the reference capacitance but a difference between the measured parasitic capacitance and the reference capacitance is smaller or equal to a first threshold value, the processor 220 may determine that the measured parasitic capacitance and the reference capacitance are similar and the pressure sensor 282 operates normally. When the measured parasitic capacitance is not equal to the reference capacitance but the difference between the measured parasitic capacitance and the reference capacitance is larger than the first threshold, the processor 220 may determine that the pressure sensor 282 operates abnormally. According to one embodiment, determining whether the pressure sensor 282 operates normally based on the parasitic capacitance value may be performed every predetermined cycle and/or every time a predetermined event occurs.

According to various embodiments, when the pressure sensor 282 operates normally, the processor 220 may determine whether a user input applied to the display 260 via the touch sensor 281 and the pressure sensor 282 is a touch input or a pressure input. According to one embodiment, when the touch input to the display 260 is detected through the touch sensor 281, the processor 220 may detect a pressure value for the touch input via the pressure sensor 282. When the pressure value detected via the pressure sensor 282 is within a predetermined effective range but is smaller than a second threshold value (e.g., 0<detected pressure value<second threshold value), the processor 220 may determine that the touch input is detected. The processor 220 may perform a touch input-related function mapped to a region in which the touch input is detected, in response to the detection of the touch input. For example, when “touch input-first application execution” and “pressure input-home screen display” are mapped to a first region in which the touch input is detected, the processor 220 may execute a first application in response to the detection of the touch input. When the pressure value detected via the pressure sensor 282 is within the predetermined effective range and is equal to or larger than the second threshold value (e.g., detected pressure value>second threshold value>0), the processor 220 may determine that the pressure input is detected. The processor 220 may perform a pressure input-related function mapped to a region in which the pressure input is detected, in response to the detection of the pressure input. For example, when “touch input-first function execution” and “pressure input-home screen display” are mapped to a first region in which the pressure input is detected, the processor 220 may control the display 260 so that the home screen is displayed, in response to the detection of the pressure input.

According to various embodiments, when the pressure sensor 282 operates abnormally, the processor 220 may perform a function corresponding to the pressure input using a touch input to at least a partial region of the display 260. According to one embodiment, the at least a partial region of the display 260 may be set as any region in which the pressure input can be detected via the pressure sensor 282 during the normal operation of the pressure sensor 282. For example, when the pressure sensor 282 is arranged in the P1 region 120, the at least a partial region of the display 260 may be set as the P1 region 120 and a region adjacent to the P1 region 120 from the entire of the display 260. As another example, when the pressure sensor 282 is arranged in the P2 region 122, the at least a partial region of the display 260 may be set as the P2 region 122 which is the entire region of the display 260. According to one embodiment, the at least a partial region of the display 260 may be set as at least a partial region of any region in which the pressure input can be detected via the pressure sensor 282 during the normal operation of the pressure sensor 282. For example, when the pressure sensor 282 is arranged in the P1 region 120, the at least a partial region of the display 260 may be set as at least a partial region among the P1 region and a region adjacent to the P1 region. As another example, when the pressure sensor 282 is arranged in the P2 region 122, the at least a partial region of the display 260 may be set as at least a partial region of the P2 region 122. The at least a partial region of the display 260 may be set or changed by a designer and/or a user. For example, the at least a partial region of the display 260 may be set as a top region, a bottom region, a left region, a right region, a central region, or a combination of two or more regions thereof on the screen of the display 260. According to one embodiment, when the pressure sensor 282 operates abnormally, the processor 220 may detect a touch input to a first region of the at least a partial region of the display 260 using the touch sensor 281, and may perform a function corresponding to a pressure input to the first region, in response to the detected touch input. The first region may be a region to which a function of the electronic device associated with the pressure input is mapped. For example, the first region may be a region to which a function of the electronic device associated with the pressure input such as “pressure input-home screen display” or “pressure input-first application execution” is mapped. The function of the electronic device may include an operation and/or a control command of the electronic device.

According to various embodiments, the processor 220 may control a display for the at least a partial region of the display 260 based on whether the pressure sensor 282 operates normally. According to one embodiment, when the pressure sensor 282 operates normally, the processor 220 may display a first user interface in the at least a partial region of the display 260. At least a part of the first user interface may include a first object associated with a touch input and may not include a second object associated with a pressure input to the first region. According to one embodiment, when the pressure sensor 282 operates abnormally, the processor 220 may display a second user interface in the at least a partial region of the display 260. At least a part of the second user interface may include a first object associated with a touch input and may not include a second object associated with a pressure input to the first region. According to one embodiment, the first object and/or the second object may include at least one of an icon, a symbol, a video, an image, and text. The second object may be displayed in the first region. The second object may include a symbol representing a function of the electronic device (e.g., home screen display, backward function, recently executed application display, volume adjustment, or an application execution). When a touch input is received through the second object, the processor 220 may perform the function of the electronic device associated with a pressure input mapped to the first region. According to one embodiment, when the pressure sensor 282 operates abnormally, the processor 220 may control the display region of at least one first object, which is displayed in the first region of the display 260, to be changed and may control the second object to be displayed in the first region of the display 260. For example, when “pressure input-home screen display” and “touch input-first application execution” are mapped to the first region, the processor 220 may control the display 260 so that the first object associated with the first application execution is displayed in the first region while the pressure sensor 282 operates normally, and may not display the second object associated with the pressure input and/or the home screen display or set the display state of the second object to a hidden state. When it is detected that the pressure sensor 282 operates abnormally, the processor 220 may change the display position of the first object so that the first object displayed in the first region of the display 260 may be displayed in another region, and may display the second object (e.g., home button symbol) associated with the pressure input to the first region. When a touch input to the second object is detected, the processor 220 may control a function associated with the pressure input to the first region to be performed.

According to various embodiments, the processor 220 may control the resolution of a service screen based on whether the pressure sensor 282 operates normally. The service screen may include at least one of, for example, an application execution screen, an always on display (AOD) screen, a home screen, and an operation execution screen according to user input. According to one embodiment, when the pressure sensor 282 operates normally, the processor 220 may control the service screen requested by a user input to be displayed at a first resolution. For example, when the pressure sensor 282 operates normally, the processor 220 may display the service screen at the first resolution to display the service screen in the first region of the display 260 or not to display an object associated with the pressure input. According to one embodiment, when the pressure sensor 282 operates abnormally, the processor 220 may change the resolution of the service screen which is currently displayed. For example, when an abnormal operation of the pressure sensor 282 is detected, the processor 220 may change the resolution of the service screen which is displayed in the first region of the display 260. When the service screen is displayed in the first region of the display 260, the processor 220 may adjust and display the resolution of the service screen so that the service screen may be controlled not to be displayed in the first region of the display 260. The processor 220 may display an object associated with the pressure input in the first region of the display 260. For example, in a state in which “pressure input-home screen display function” is mapped to the first region of the display 260 while an execution screen of the first application is displayed in the entire region of the display 260, the abnormal operation of the pressure sensor 282 may be detected. In this case, the processor 220 may reduce the resolution of the execution screen of the first application and may display an object associated with a pressure input function (e.g., home screen display) in the first region. When a touch input to the displayed object is detected, the processor 220 may control the function associated with the pressure input to the first region to be performed.

According to one embodiment, when an abnormal operation of the pressure sensor 282 is detected, the processor 220 may output a message indicating that the abnormal operation of the pressure sensor is detected. For example, the processor 220 may control a message, an icon, and/or graphical data indicating the detection of an abnormal operation of the pressure sensor to be displayed on the display 260. As another example, the processor 220 may output a voice message indicating that an abnormal operation of the pressure sensor is detected. As another example, the processor 220 may output haptic data indicating that an abnormal operation of the pressure sensor is detected.

The memory 230 may include a volatile or non-volatile memory. The memory 230 may store, for example, instructions or data relevant to at least one other component of the electronic device 201. According to one embodiment, the memory 230 may store software or a program 240. For example, the program 240 may include a kernel 241, a middleware 243, an application programming interface (API) 245, or an application program (or “application”) 247. At least some of the kernel 241, the middleware 243, and the API 245 may be referred to as an operating system (OS).

The kernel 241 may control or manage system resources (e.g., the bus 210, the processor 220, or the memory 230) used for performing an operation or function implemented by the other programs (e.g., the middleware 243, the API 245, or the application 247). Furthermore, the kernel 241 may provide an interface through which the middleware 243, the API 245, or the application 247 may access the individual components of the electronic device 201 to control or manage the system resources.

The middleware 243 may function as, for example, an intermediary for allowing the API 245 or the application 247 to communicate with the kernel 241 to exchange data. In addition, the middleware 243 may process one or more task requests received from the application 247 according to priorities thereof. For example, the middleware 243 may assign priorities for using the system resources (e.g., the bus 210, the processor 220, the memory 230, or the like) of the electronic device 201, to at least one of the application 247, and may process the one or more task requests. The API 245 is an interface through which the applications 247 control functions provided from the kernel 241 or the middleware 243, and may include, for example, at least one interface or function (e.g., instruction) for file control, window control, image processing, or text control.

The input/output interface 250 may serve as an interface capable of transferring instructions or data input from a user or another external device to the other component(s) of the electronic device 201. The input/output interface 250 may output the instructions or data received from the other component(s) of the electronic device 201 to the user or an external electronic device. According to one embodiment, the input/output interface 250 may include a key pad, a dome switch, a physical button, a touch panel, and a jog & shuttle. The input/output interface 250 may be, for example, one or more sensor devices capable of receiving sensor data related to biometric information, motion, temperature, sound, image, and the like.

The display 260 may include, for example, a liquid crystal display (LCD), a light emitting diode (LED) display, an organic LED (OLED) display, a micro-electro-mechanical systems (MEMS) display, or an electronic paper display. The display 260 may display, for example, various types of content (e.g., text, images, videos, icons, and/or symbols) to the user. The display 260 may include a touch screen (e.g., touch sensor 281), and may receive, for example, a touch, gesture, proximity, or hovering input using an electronic pen or a body part of a user.

The sensor 280 may detect a user input to the display 260. The sensor 280 may include a touch sensor 281 that detects a touch input to the display 260 and a pressure sensor 282 that detects a pressure input to the display 260. According to one embodiment, the pressure sensor 282 may be attached to one surface of the display 260 through an adhesive. According to one embodiment, the pressure sensor 282 may be detached from the display 260 by an external impact or the like.

The communication interface 270 may support communication between the electronic device 201 and an external device (e.g., accessory device, electronic device 204, or server 206). For example, the communication interface 270 may be connected to a network 262 through wireless or wired communication and thereby communicate with the external device (e.g., electronic device 204 or server 206). In another example, the communication interface 270 may be connected to directly an electronic device 202 through wireless or wired communication 264. The wireless communication may include, for example, cellular communication including at least one of LTE, LTE Advance (LTE-A), code division multiple access (CDMA), wideband CDMA (WCDMA), universal mobile telecommunications system (UMTS), Wireless Broadband (WiBro), Global System for Mobile Communications (GSM), and 5G network. According to one embodiment, the wireless communication may include, for example, Wi-Fi, light fidelity (Li-Fi), Bluetooth (BT), Bluetooth low energy (BLE), Zigbee, near field communication (NFC), magnetic secure transmission, radio frequency (RF), a body area network (BAN), or a GNSS. The wired communication may include at least one of a universal serial bus (USB), a high definition multimedia interface (HDMI), recommended standard 232 (RS-232), power line communication, optical communication, and a plain old telephone service (POTS).

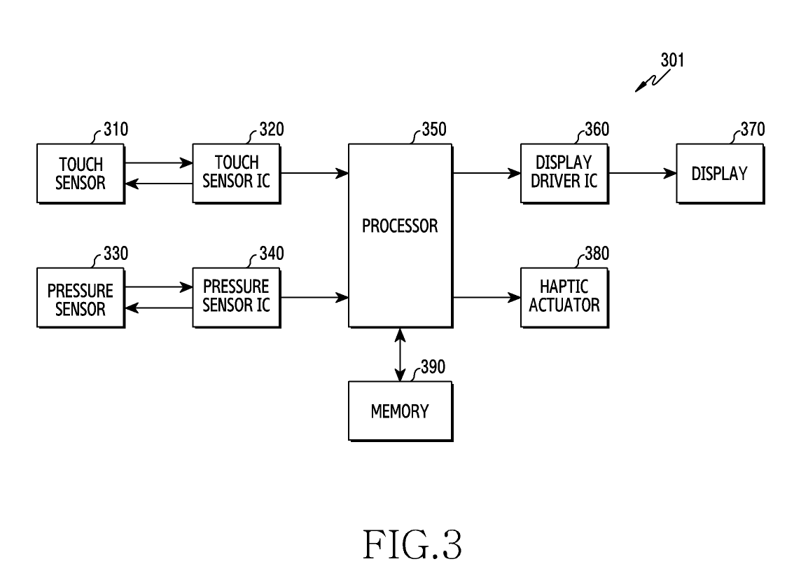

FIG. 3 is a block diagram illustrating the relationship between some of components included in an electronic device according to various embodiments of the disclosure. An electronic device 301 of FIG. 3 may be the electronic device 100 illustrated in FIG. 1 and/or the electronic device 201 illustrated in FIG. 2.

Referring to FIG. 3, the electronic device 301 may include a touch sensor 310, a touch sensor integrated circuit (IC) 320, a pressure sensor 330, a pressure sensor IC 340, a processor 350, a display driver IC 360, a display 370, a haptic actuator 380, and a memory 390. According to some embodiments, the electronic device 201 may omit at least one of the components or may additionally include other components.

According to various embodiments, the touch sensor 310 may detect a touch input of a user to the display 370. The touch sensor 310 may be a capacitive, resistive, infrared, or electromagnetic inductive touch sensor. The above-described touch sensors are illustrative, and various embodiments of the present document are not limited thereto. The touch sensor 310 may transmit signals indicating the presence/absence of a user's touch input and/or a touch input position to the touch sensor IC 320.

According to various embodiments, the touch sensor IC 320 may transmit or receive signals (transmission signal (TX), reception signal (RX), stimulus signal (shield), etc.) to and from the touch sensor 310. The touch sensor IC 320 may detect a touch input position of a user based on the signal transmitted and received to and from the touch sensor 310. The touch sensor IC 320 may transmit the detected touch input position to the processor 350. The touch sensor IC 320 may transmit and receive signals to and from the touch sensor 310 only in a touch input-enabled region defined by the processor 350. Alternatively, even if the touch sensor IC 320 transmits and receives signals to and from the touch sensor 310 over the entire region, when the touch input position is located within the touch input-enabled region, the touch input position may be transmitted to the processor 350, and when touch input position is located outside the touch input-enabled region, the touch input position may not be transmitted to the processor 350. The touch sensor IC 320 may operate in a normal mode and/or a low power mode. In the low power mode, the touch sensor IC 320 may operate at a touch sensing frequency and/or a touch scan period lower than those in the normal mode.

According to various embodiments, the pressure sensor 330 may detect a pressure input of a user to the display 370. The pressure sensor 330 may be a capacitive, inductive, strain gauge, or piezo pressure sensor. The above-described pressure sensors are illustrative, and various embodiments of the present document are not limited thereto. The pressure sensor 330 may transmit pressure data (e.g., intensity of touch input) and/or a signal indicating a pressure input position to the pressure sensor IC 340.

According to various embodiments, the pressure sensor IC 340 may transmit or receive signals (e.g., TX, RX, stimulus signal (shield), etc.) to and from the pressure sensor 330. The pressure sensor IC 340 may transmit the detected intensity (pressure) of the touch input and/or a retention time of the pressure to the processor 350. The processor 350 or the pressure sensor IC 340 may determine the intensity (pressure) of the user's touch input and/or the retention time of the pressure based on the signal received from the pressure sensor 330. According to various embodiments, the pressure sensor IC 340 may measure a parasitic capacitance for an adhesive layer between the pressure sensor 330 and the display 370, and may transmit the measured parasitic capacitance to the processor 350.

According to various embodiments, the pressure sensor IC 340 may transmit and receive signals to and from the pressure sensor 330 only in a touch input-enabled region defined by the processor 350. Alternatively, even if the pressure sensor IC 340 transmits and receives signals to and from the pressure sensor 330 over the entire region, when a pressure input position is located within the pressure input-enabled region, the pressure input position may be transmitted to the processor 350, and when the pressure input position is located outside the pressure input-enabled region, the pressure input position may not be transmitted to the processor 350. The pressure sensor IC 340 may operate in a normal mode and/or a low power mode. In the low power mode, the pressure sensor IC 340 may operate at a pressure sensing frequency and/or a pressure scan period lower than those in the normal mode.

According to various embodiments, the processor 350 may set a user input-enabled region (e.g., touch input-enabled region, pressure input-enabled region, or the like) that can be recognized by the touch sensor IC 320 and/or the pressure sensor IC 340, and may transmit the set user input-enable region to the touch sensor IC 320 and/or the pressure sensor IC 340. The position of the user input-enabled region may be changed. The processor 350 may transmit the position of the changed user input-enabled region to the touch sensor IC 320 and/or the pressure sensor IC 340. The processor 350 may determine image information to be transmitted to the display driver IC 360, the position of the image information, and/or haptic information to be transmitted to the haptic actuator 380. For example, when the intensity of the received touch input is equal to or greater than a first threshold, the processor 350 may transmit first image information to the display driver IC 360, and may transmit first haptic information to the haptic actuator 380. For example, when the intensity of the received touch input is equal to or greater than a second threshold greater than the first threshold, the processor 350 may transmit second image information (e.g., image information obtained by enlarging at least a part of the first image information) to the display driver IC 360, and may transmit second haptic information (e.g., haptic information having intensity stronger than that of first haptic information) to the haptic actuator 380. The processor 350 may synchronize a first position and a first intensity of a touch input received at a first time, and may synchronize a second position and a second intensity of a touch input received at a second time different from the first time. The processor 350 may be switched to an inactive state after transmitting the above-described information to each module. The processor 350 may be in an inactive sate in an AOD mode. The processor 350 may maintain the inactive state in the AOD mode, may be activated by a specific event, and may transmit image information and/or control information to the display driver IC 360, the touch sensor IC 320, the pressure sensor IC 340, and the like. The processor 350 may transmit information and then may be switched to an inactive state again.

According to various embodiments, when a signal indicating a touch input position is received from the touch sensor IC 320, but pressure data associated with a touch input is not received from the pressure sensor IC 340, the processor 350 may determine that the pressure sensor 330 operates abnormally. According to various embodiments, when a signal indicating a touch input position is received from the touch sensor IC 320 and pressure data (e.g., data indicating intensity of touch input) associated with a touch input is received from the touch sensor IC 320, the processor 350 may determine whether the pressure sensor 330 operates normally based on the received pressure data. When the received pressure data is within a predetermined effective data range (e.g., received pressure data value>0), the processor 350 may determine that the pressure sensor 330 operates normally. When the received pressure data value is outside the predetermined effective data range (e.g., received pressure data value≤0), the processor 350 may determine that the pressure sensor 330 operates abnormally.

According to various embodiments, when the received pressure data is within the predetermined effective data range, the processor 350 may compare the received pressure data and predetermined effective pressure data to determine whether a pressure input to the display 370 occurs. For example, when the pressure data received from the pressure sensor IC 340 is less than the predetermined effective pressure data, the processor 350 may determine that the pressure input does not occur. As another example, when the pressure data provided from the pressure sensor IC 340 is equal to or greater than the predetermined effective pressure data, the processor 350 may determine that the pressure input occurs.

According to various embodiments, the processor 350 may determine whether the pressure sensor 330 operates normally based on a parasitic capacitance provided from the pressure sensor IC 340. When the parasitic capacitance is the same as a reference capacitance, the processor 350 may determine that the pressure sensor 330 operates normally. When the parasitic capacitance is different from the reference capacitance, the processor 350 may determine that the pressure sensor 330 operates abnormally.

According to various embodiments, the display driver IC 360 may transmit a driving signal (e.g., driver driving signal or gate driving signal) to the display 370 based on image information received from the processor 350. The display 370 may display various graphic objects (e.g., images, videos, text, messages, icons, and/or symbols) based on signals from the display driver IC 360.

According to various embodiments, the haptic actuator 380 may generate various tactile effects that a user may feel based on signals received from the processor 350. For example, the haptic actuator 380 may provide various types of vibration feedback. The haptic actuator 380 may be disposed under the pressure sensor to provide vibration feedback based on a signal indicating that the pressure input is detected.

According to various embodiments, the memory 390 may store instructions or data that cause the processor 350 to perform the above-described operations, and may include a volatile or non-volatile memory.

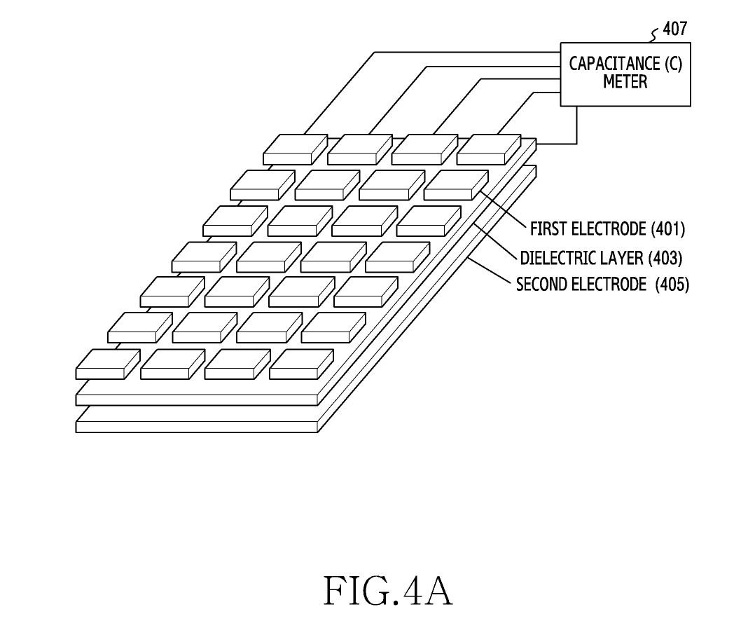

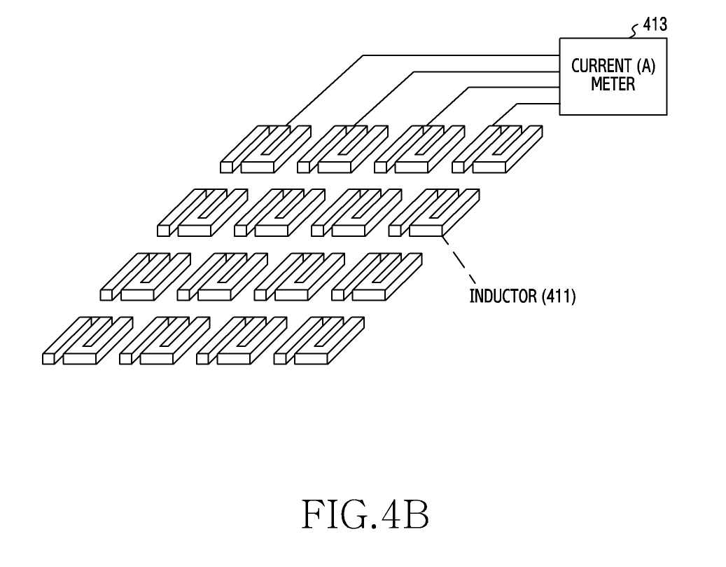

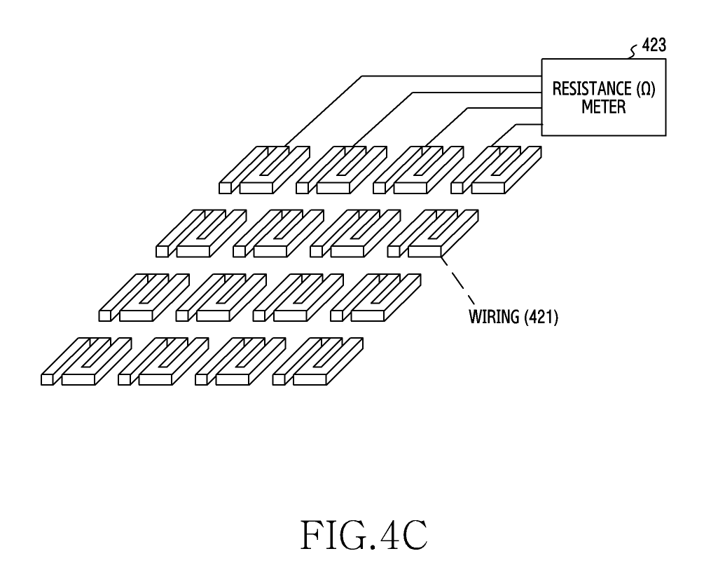

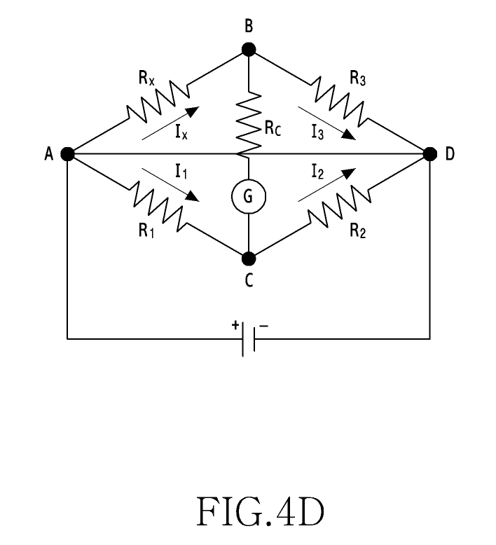

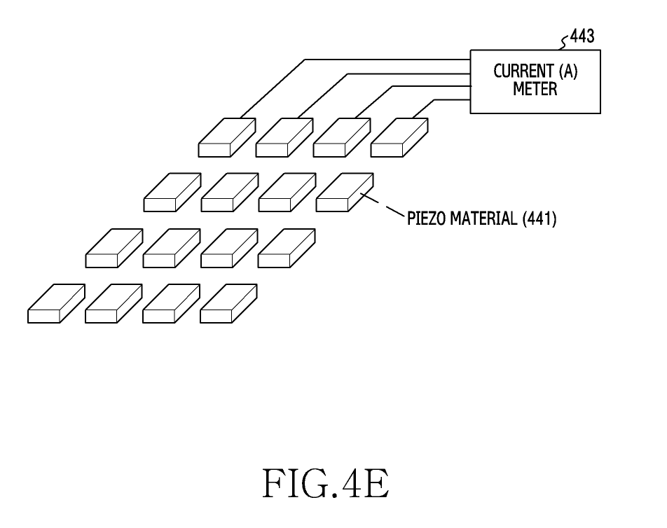

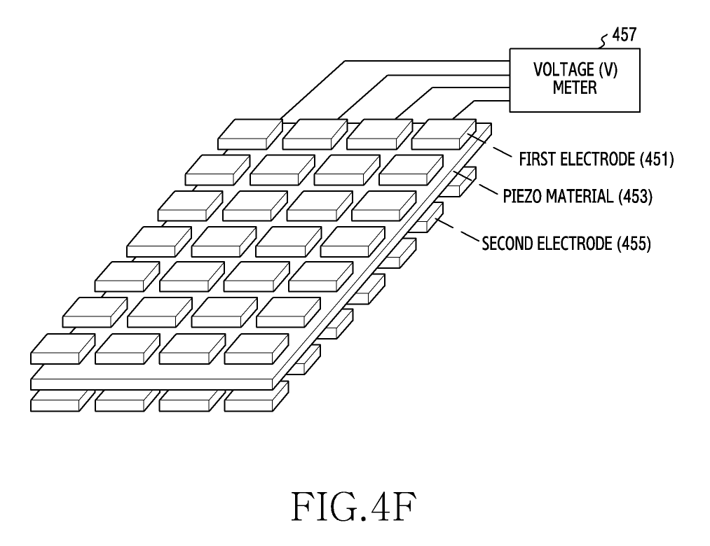

FIGS. 4A, 4B, 4C, 4D, 4E, and 4F illustrate circuit configurations of a pressure sensor according to various embodiments of the disclosure.

Referring to FIG. 4A, a capacitive pressure sensor may include a first electrode 401, a dielectric layer 403, a second electrode 405, and a capacitance meter 407. According to one embodiment, the capacitive pressure sensor may detect corresponding pressure based on the change amount of a capacitance formed between the first electrode 401 and the second electrode 405. For example, the capacitive pressure sensor may measure the change amount of the capacitance formed between the first electrode 401 and the second electrode 405 according to a user's pressure, using the capacitance meter 407, and may generate data indicating the intensity of the corresponding pressure based on the measured change amount of the capacitance. The change amount of the capacitance may increase along with a reduction in a distance between the first electrode 401 and the second electrode 405 due to the pressure of a user applied to the displays 260 and 370. According to one embodiment, the capacitive pressure sensor may use the capacitance meter 407 to check a position where the change in the capacitance is detected, and may generate data indicating a position where the corresponding pressure is detected based on the position where the change in the capacitance is detected.

Referring to FIG. 4B, an inductive pressure sensor may include an inductor 411 and a current meter 413. According to one embodiment, the inductive pressure sensor may detect pressure based on the change amount of a current induced in the inductor 411 (e.g., coil). For example, the inductive pressure sensor may measure the change amount of the current induced in the inductor 411 according to user's pressure, using the current meter 413, and may generate data indicating the intensity of the pressure based on the measured change amount of the current. The change amount of the current may increase as a conductor (e.g., metal housing, user fingers, etc.) is brought closer to an inductor disposed in the housing by the user's pressure applied to the displays 260 and 370. According to one embodiment, the inductive pressure sensor may use the current meter 413 to check a position where the change in the current is detected, and may generate data indicating a position where the pressure is detected based on the position where the change in the current is detected.

Referring to FIG. 4C, a strain gauge pressure sensor may include a wiring 421 and a resistance meter 423. According to one embodiment, the strain gauge pressure sensor may detect corresponding pressure based on the change amount of resistance of the wiring (e.g., conductor). For example, the strain gauge pressure sensor may use the resistance meter 423 to measure the change amount of resistance of the conductor according to the user's pressure, and may generate data indicating the intensity of the pressure, data indicating a position where the change amount of resistance is measured, or a combination thereof based on the measured change amount of resistance. The change amount of resistance may increase along with an increase in the length of the conductor by the user's pressure applied to the displays 260 and 370. For example, the cross-sectional area of the conductor may be reduced due to the increase in the length of the conductor and thereby the change amount of resistance maybe increased. The wiring in the strain gauge pressure sensor may be configured in the form of a Wheatstone Bridge as illustrated in FIG. 4D. According to one embodiment, the strain gauge pressure sensor may use the resistance meter 423 to check the position where the change in the resistance is detected and to generate data indicating the position where the pressure is detected based on the position where the change in the resistance is detected.

Referring to FIG. 4E, the piezoelectric pressure sensor may include a piezo material 441 and a current meter 443. Alternatively, referring to FIG. 4F, the piezoelectric pressure sensor may include a first electrode 451, a piezo material 453, a second electrode 455, and a voltage meter 457. According to one embodiment, the piezoelectric pressure sensor may detect corresponding pressure based on a difference in the current or voltage which occurs by the piezo material. For example, the piezoelectric pressure sensor may use the current meter 443 or the voltage meter 457 to measure the difference in the current or voltage which occurs by the piezo materials 441 and 453 according to user's pressure and to generate data indicating the intensity of the pressure based on the measured difference in the current or voltage. The difference in the current or voltage may increase along with an increase in the amount of a current converted by the piezo material. According to one embodiment, the piezoelectric pressure sensor may use the current meter 443 or the voltage meter 457 to check a position where the change in the current or voltage is detected, and to generate data indicating a position where the pressure is detected based on the position where the change in the current or voltage is detected.

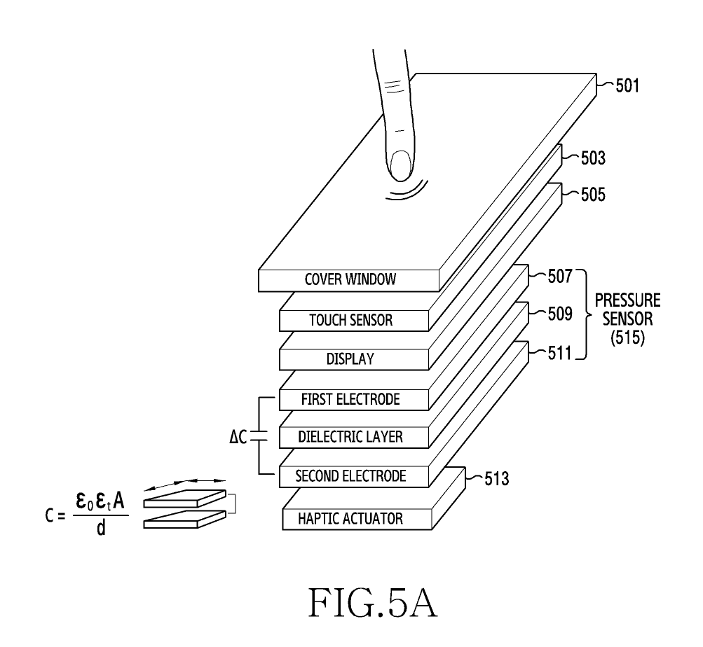

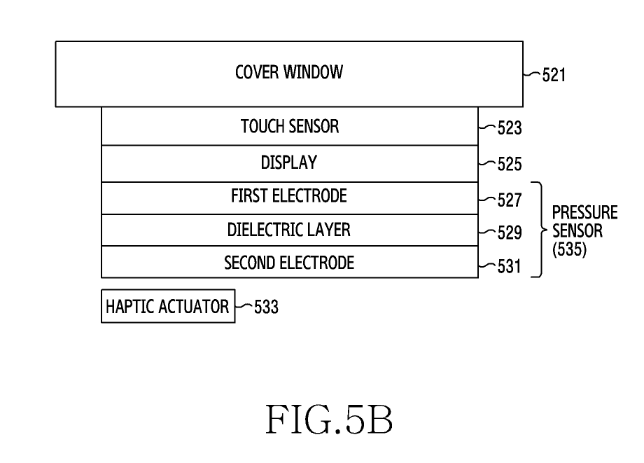

FIG. 5A is a perspective diagram illustrating an electronic device including a capacitive pressure sensor according to various embodiments of the disclosure. FIG. 5B is a cross-sectional diagram illustrating an electronic device including a capacitive pressure sensor according to various embodiments of the disclosure. The electronic device of FIGS. 5A and 5B may be the electronic device 100 of FIG. 1, the electronic device 201 of FIG. 2, and/or the electronic device 301 of FIG. 3.

Referring to FIGS. 5A and 5B, the electronic device may include cover windows 501 and 521, touch sensors 503 and 523, displays 505 and 525, pressure sensors 515 and 525, and haptic actuators 513 and 533.

According to various embodiments, the cover windows 501 and 521 may include a substantially rigid layer such as glass (including reinforced glass or sapphire glass) or a substantially flexible layer such as a polymer (PI, PET, or PC).

Although the touch sensors 503 and 523 are illustrated as being arranged between the cover windows 501 and 521 and the displays 505 and 525, the touch sensors 503 and 523 may be arranged at least partially (at least one electrode layer) inside the display. The touch sensor may be implemented by a self-capacitance or mutual capacitance method.

According to various embodiments, the displays 505 and 525 may include an LCD, a light emitting diode (LED) display, an organic light emitting diode (OLED) display, a quantum dot display, a microelectromechanical system (MEMS) display, and an electronic paper display.

According to various embodiments, the pressure sensors 515 and 535 may include first electrodes 507 and 527, second electrodes 511 and 531, and dielectric layers 509 and 529 disposed therebetween.

According to various embodiments, the pressure sensors 515 and 535 may be arranged under the displays 505 and 525, as illustrated in FIGS. 5A and 5B. When the pressure sensors 515 and 535 are arranged under the displays 505 and 525, the first electrodes 507 and 527 or the second electrodes 511 and 531 of the pressure sensors 515 and 535 are integrally formed with the display or may be arranged on a separate support member (e.g., flexible printed circuit board (FPCB)).

According to various embodiments, the pressure sensors 515 and 535 may be arranged between the cover windows 501 and 521 and the displays 505 and 525. When the pressure sensors 515 and 535 are arranged between the cover windows 501 and 521 and the displays 505 and 525, the first electrodes 507 and 527 or the second electrodes 511 and 531 of the pressure sensors 515 and 535 may be arranged integrally with the touch sensors 503 and 523 or may be arranged on a separate support member (e.g., polyethylene terephthalate (PET)).

According to various embodiments, the pressure sensors 515 and 535 may be arranged at least partially (at least one electrode layer) inside the displays 505 and 525. When the pressure sensors 515 and 535 are arranged inside the displays 505 and 525, the first electrodes 507 and 527 or the second electrodes 511 and 531 of the pressure sensors 515 and 535 may be arranged between display electrodes.

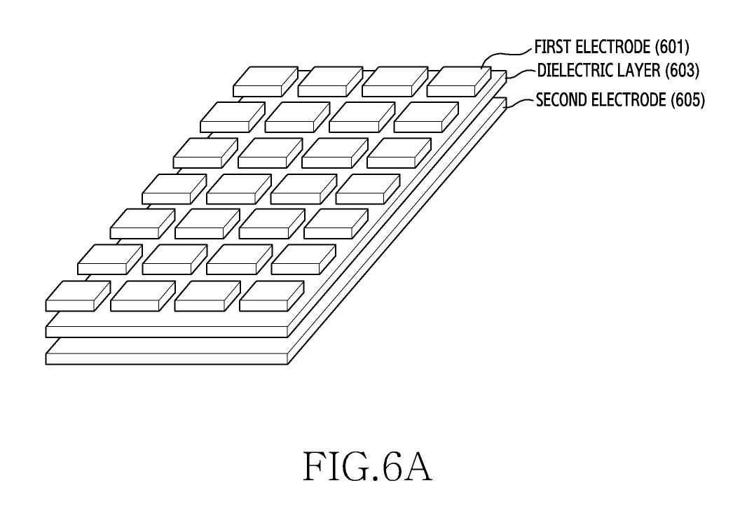

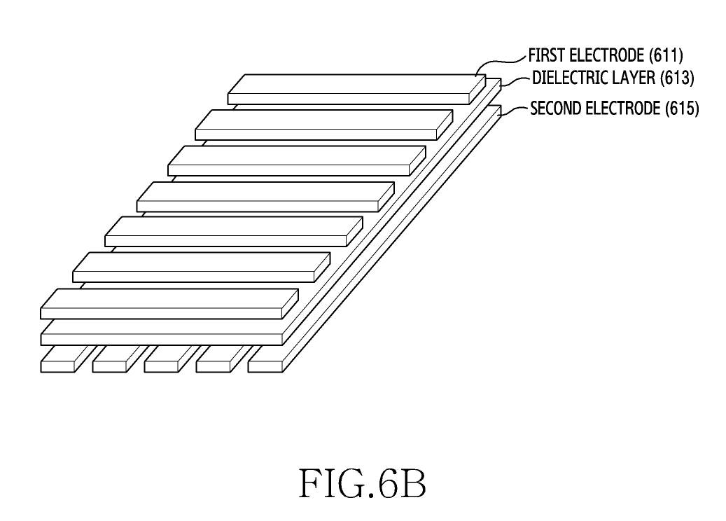

According to various embodiments, the pressure sensors 515 and 535 may be implemented by a self-capacitance method or a mutual capacitance method. This will be described later with reference to FIGS. 6A and 6B.

According to various embodiments, the haptic actuators 513 and 533 may be arranged under the pressure sensors 515 and 535. For convenience of description in FIGS. 5A and 5B, one haptic actuator 513 or 533 may be arranged on the pressure sensors 515 and 535. However, according to various embodiments, a plurality of haptic actuators 513 and 533 may be arranged at various locations of the electronic device. The haptic actuators 513 and 533 may provide various types of vibration feedback to all or part of the electronic device.

According to various embodiments, the sizes of the pressure sensors 515 and 535 may be smaller than the sizes of the touch sensors 503 and 523 and/or the displays 505 and 525, as illustrated in FIGS. 5A and 5B. However, this is illustrative and the disclosure is not limited thereto. For example, the sizes of the pressure sensors 515 and 535 may be the same as the sizes of the touch sensors 503 and 523 and/or the displays 505 and 525.

FIGS. 6A and 6B are perspective diagrams illustrating a pressure sensor according to various embodiments of the disclosure. FIG. 6A is a perspective diagram illustrating a self-capacitive pressure sensor and FIG. 6B is a perspective diagram illustrating a mutual capacitive pressure sensor.

According to various embodiments, as illustrated in FIG. 6A, the self-capacitive pressure sensor may include a first electrode 601 in the form of a repeated plurality of polygons (or circles), a second electrode 602 extending all over the entire region corresponding to the repeated plurality of polygons, and a dielectric layer 603 disposed between the first electrode 601 and the second electrode 605. The self-capacitive pressure sensor may sense corresponding pressure based on a change in the capacitance between each partial electrode of the first electrode 601 and the second electrode 605. The positions or shapes of the first electrode 601 and the second electrode 605 may be mutually changed.

Referring to FIG. 6A, the mutual capacitive pressure sensor may include a first electrode 611 extending in a first direction, a second electrode 615 extending in a second direction substantially perpendicular to the first direction, and a dielectric layer 613 disposed between the first electrode 611 and the second electrode 615. The mutual capacitive pressure sensor may sense corresponding pressure based on a change in the capacitance between the first electrode 611 and the second electrode 615 at a point where the first electrode 611 and the second electrode 615 cross each other. The positions or shapes of the first electrode 611 and the second electrode 615 may be mutually changed.

According to various embodiments, the first electrodes 601 and 611 or the second electrodes 605 and 615 in the self-capacitive pressure sensor and/or mutual capacitive pressure sensor may be opaque or transparent. That is, when a user views the pressure sensor, an object disposed opposite the pressure sensor may be not visible (opaque) or visible (transparent). When the first electrodes 601 and 611 or the second electrodes 605 and 615 are opaque, the first electrodes 601 and 611 or the second electrodes 605 and 615 may be made of at least one of Cu, Ag, Mg, and Ti, or a combination of two or more thereof. When the first electrodes 601 and 611 or the second electrodes 605 and 615 are transparent, the first electrodes 601 and 611 or the second electrodes 605 and 615 may be made of at least one of ITO, IZO, a polymeric conductor, graphene, and a non-transparent wiring pattern (Ag nanowire or metal mesh) having a specific line width or less or a combination of two or more thereof.

According to various embodiments, the dielectric layers 603 and 613 may include at least one of silicon, air, foam, membrane, OCA, sponge, rubber, ink, and polymer (PC, PET, etc.).

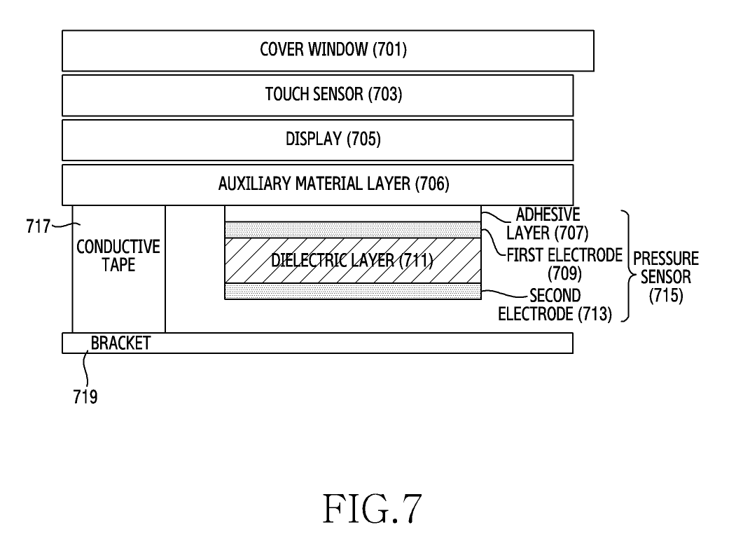

FIG. 7 is a perspective diagram illustrating an electronic device showing the position of a pressure sensor according to various embodiments of the disclosure.

Referring to FIG. 7, a touch sensor 703 may be disposed under a cover window 701, and a display 705 may be disposed under the touch sensor 703. The touch sensor 703 and the display 705 may be combined and referred to as one touch screen display (e.g., 101).

According to various embodiments, an auxiliary material layer 706 including a conductive member may be disposed below the display 705. For example, the auxiliary material layer 706 may include an electrode layer such as a Cu sheet or a Cu & Gr sheet. The auxiliary material layer 706 may be connected to a bracket 719 through a conductive tape 717.

According to various embodiments, the conductive tape 717 may be disposed between the auxiliary material layer 706 and the bracket 719. According to one embodiment, the conductive tape 717 may include a waterproof member. According to one embodiment, the conductive tape 717 may serve to bond the auxiliary material layer 706 and the bracket 719 to each other. According to one embodiment, when the bracket is made of a metal material and contributes to the ground, the conductive tape 717 may serve to electrically connect the auxiliary material layer 706 and the bracket.

According to various embodiments, the bracket 719 may be a housing including a conductive member and/or a non-conductive member.

According to various embodiments, the pressure sensor 715 may be disposed between the auxiliary material layer 706 and the bracket 719. The pressure sensor 715 may include a first electrode 709, a second electrode 713, and a second dielectric layer 711 between the first electrode 709 and the second electrode 713. The pressure sensor 715 may be attached to at least a partial region of the auxiliary material layer 706 through an adhesive layer 707. For example, the first electrode 709 of the pressure sensor 715 may be attached to the auxiliary material layer 706 through the adhesive layer 707. According to one embodiment, the adhesive layer 707 may include an adhesive member for attaching the pressure sensor 282 and the auxiliary material layer 706. According to one embodiment, the adhesive layer 707 may be a dielectric layer.

The pressure sensor 715 according to one embodiment may not be attached to the bracket 719 and/or the conductive tape 717. For example, an air layer may be present between the pressure sensor 715 and the bracket 719 or between the pressure sensor 715 and the conductive tape 717.

According to various embodiments, the pressure sensor 715 may measure the change amount of a capacitance (e.g., a self-capacitance or a mutual capacitance) formed in the dielectric layer 711 between the first electrode 709 and the second electrode 713. The pressure sensor 715 may generate pressure data based on the measured change amount of the capacitance. According to one embodiment, when the first electrode 709 of the pressure sensor 715 is normally attached to the auxiliary material layer 706 through the adhesive layer 707, the pressure applied to the cover window 701 may be transmitted to the first electrode 709 and/or the second electrode 713 via the touch sensor 703, the display 705, and the auxiliary material layer 706, so that the pressure sensor 715 may measure the change amount of the capacitance according to a change in a distance between the first electrode 709 and the second electrode 713. According to one embodiment, when at least a portion of the first electrode 709 of the pressure sensor 715 is not attached to the auxiliary material layer 706, the pressure applied to the cover window 701 cannot be transmitted to the first electrode 709 and/or the second electrode 713, so that the pressure sensor 715 cannot measure the change amount of the capacitance. For example, the distance between the first electrode 709 and the second electrode 713 of the pressure sensor 715 is not changed so that the capacitance formed in the dielectric layer 711 between the first electrode 709 and the second electrode 713 may not be changed. Thus, the electronic device according to various embodiments of the present document may determine whether the pressure sensor 715 operates normally based on the change amount of the capacitance of the pressure sensor 715.

According to various embodiments, the pressure sensor 715 may measure a parasitic capacitance formed in the adhesive layer 707 between the first electrode 709 and the auxiliary material layer 706. According to one embodiment, when the first electrode 709 of the pressure sensor 715 is normally attached to the auxiliary material layer 706 through the adhesive layer 707, the parasitic capacitance may maintain a constant value (e.g., a reference capacitance value). According to one embodiment, when at least a portion of the first electrode 709 of the pressure sensor 715 is not attached to the auxiliary material layer 706, the parasitic capacitance may not maintain a constant value. For example, the parasitic capacitance when the pressure sensor 715 is not attached to the auxiliary material layer 706 may be smaller than the parasitic capacitance when the pressure sensor 715 is normally attached to the auxiliary material layer 706. Thus, the electronic device according to various embodiments of this document may determine whether the pressure sensor 715 operates normally based on the parasitic capacitance between the pressure sensor 715 and the auxiliary material layer 706.

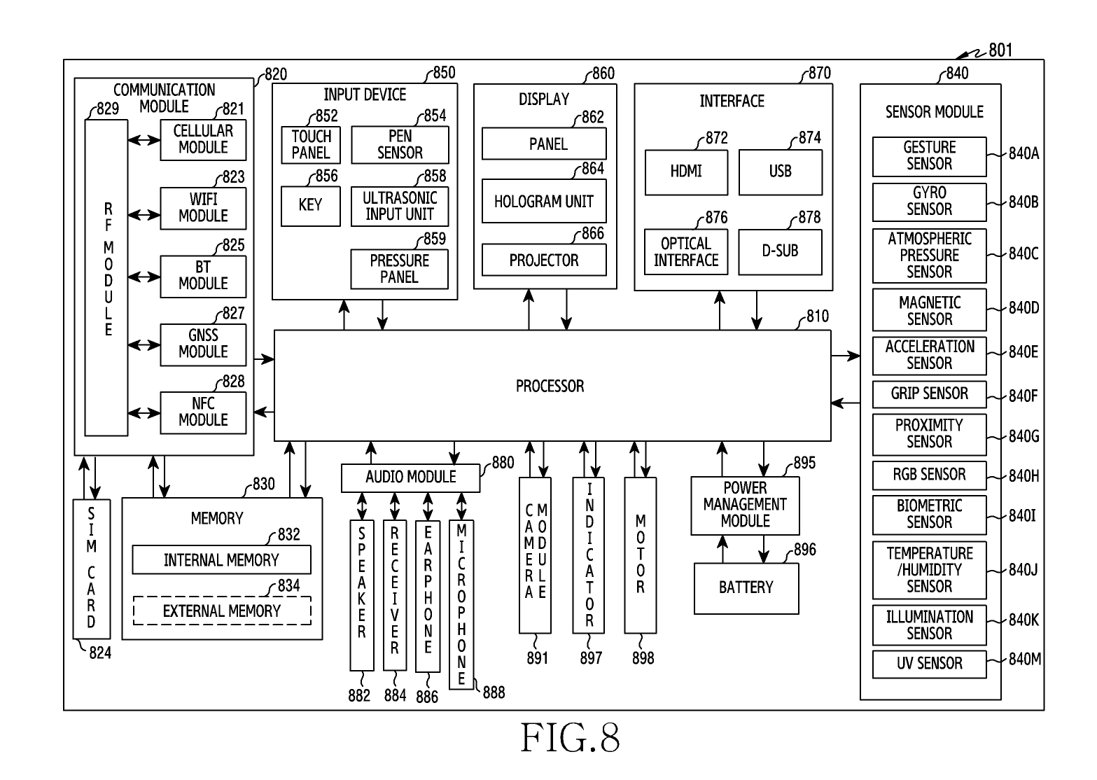

FIG. 8 is a detailed block diagram illustrating an electronic device according to various embodiments of the disclosure. The electronic device 801 of FIG. 8 may include all or some of the components of the electronic device 201, for example, illustrated in FIG. 2. The electronic device 801 of FIG. 8 may include all or some of the components of the electronic device 301, for example, illustrated in FIG. 3.

Referring to FIG. 8, the electronic device 801 may include one or more processors (e.g., AP) 810, a communication module 820, a subscriber identification module 824, a memory 830, a sensor module 840, an input device 850, a display 860, an interface 870, an audio module 880, a camera module 891, a power management module 895, a battery 896, an indicator 897, and a motor 898.

The processor 810 may drive, for example, an operating system or an application program to control a plurality of hardware or software components connected to the processor 810, may process various types of data, and may perform various operations. The processor 810 may be implemented as, for example, a system on chip (SoC). According to an embodiment, the processor 810 may further include a graphic processing unit (GPU) or an ISP. The processor 810 may load commands or data received from at least one of other components (e.g., a nonvolatile memory) on a volatile memory, may process the loaded commands or data, and may store the resultant data in a non-volatile memory.

According to various embodiments, the processor 810 may control a function for processing a user input to a first region of the display 860 based on whether the pressure sensor operates normally. The first region may be, for example a region in which a pressure input can be detected when the pressure sensor operates normally. According to one embodiment, when a pressure input to the first region of the display 860 is detected while the pressure sensor operates normally, the processor 810 may perform a first function corresponding to the pressure input to the first region. According to one embodiment, when a touch input to the first region of the display 860 is detected while the pressure sensor operates normally, the processor 810 may perform a second function corresponding to the touch input to the first region. According to one embodiment, when the touch input to the first region of the display 860 is detected while the pressure sensor operates abnormally, the processor 810 may perform the first function corresponding to the pressure input to the first region in response to the detection of the touch input.

The communication module 820 may have the same or similar configurations as the communication interface 270 of FIG. 2. For example, the communication module 820 may include a cellular module 821, a Wi-Fi module 823, a Li-Fi module 824, a BT module 825, a GNSS module 827, an NFC module 828, and an RF module 829. The cellular module 821 may provide, for example, a voice call, a video call, a short message service (SMS), or an Internet service through a communication network. According to one embodiment, the cellular module 821 may identify and authenticate the electronic device 801 in a communication network by using the subscriber identification module (e.g., SIM card). The RF module 829 may transmit and receive, for example, communication signals (e.g., RF signal).

The memory 830 (e.g., memory 230 of FIG. 2) may include an internal memory 832 or an external memory 834. The internal memory 832 may include at least one of a volatile memory (e.g., DRAM, SRAM, or SDRAM) and a non-volatile memory (e.g., a one-time programmable ROM (OTPROM), PROM, EPROM, EEPROM, a mask ROM, a flash ROM, a flash memory, a hard drive, a solid state drive (SSD), or the like). The external memory 834 may include a flash drive, e.g., a compact flash (CF), a secure digital (SD), a Micro-SD, a Mini-SD, an extreme digital (xD), a multi-media card (MMC), a memory stick, etc. The external memory 834 may be functionally or physically connected to the electronic device 801 through various interfaces.

The sensor module 840 may measure/detect a physical quantity or an operation state of the electronic device 801, and may convert the measured or detected information into an electrical signal. The sensor module 840 may include at least one of a gesture sensor 840A, a gyro sensor 840B, an atmospheric pressure sensor 840C, a magnetic sensor 840D, an acceleration sensor 840E, a grip sensor 840F, a proximity sensor 840G, a color sensor 840H (e.g., a red, green and blue (RGB) sensor), a biometric sensor 840I, a temperature/humidity sensor 840J, an illuminance sensor 840K, and an ultraviolet (UV) sensor 840M. The sensor module 840 may further include a control circuit for controlling one or more sensors belonging thereto.

The input device 850 may include at least one of, for example, a touch panel 852, a (digital) pen sensor 854, a key 856, an ultrasonic input device 858, and a pressure panel 859. The touch panel 852 may use at least one of a capacitive touch system, a resistive touch system, an infrared touch system, and an ultrasonic touch system. The touch panel 852 may further include a control circuit. The touch panel 852 may also further include a tactile layer to provide a tactile response to a user. The (digital) pen sensor 854 may be implemented with a part of the touch panel or with a separate recognition sheet. The key 856 may include, for example, a physical button, an optical key, or a keypad. The ultrasonic input device 858 may detect ultrasonic waves, created in an input tool, through a microphone (e.g., microphone 888), and may identify data corresponding to the detected ultrasonic waves. The pressure panel 859 may include a pressure sensor using at least one of a capacitive system, an inductive system, a strain gauge system, and a piezoelectric system. In addition, the pressure panel 859 may further include a control circuit.

The display 860 (e.g., display 260 of FIG. 2) may include a panel 862, a hologram unit 864, a projector 866, or a control circuit for controlling them. The panel 862 may be implemented, for example, to be flexible, transparent, or wearable. The panel 862 may be configured as one or more modules together with the touch panel 852. The hologram device 864 may show a stereoscopic image in the air by using light interference. The projector 866 may display an image by projecting light onto a screen. The screen may be located inside or outside of the electronic device 801. The interface 870 may include, for example, a HDMI 872, a USB 874, an optical interface 876, or a D-subminiature (D-sub) 878. The interface 870 may be included in the communication interface 270 illustrated in FIG. 2.

The audio module 880 may bidirectionally convert a sound and an electrical signal. At least some of the components in the audio module 880 may be included in the input/output interface 250 illustrated in FIG. 2. The audio module 880 may process sound information input or output through a speaker 882, a receiver 884, an earphone 886, a microphone 888, etc.

The camera module 891 refers to a device capable of taking both still and moving images. According to one embodiment, the camera module 891 may include one or more image sensors (e.g., a front image sensor or a rear image sensor), a lens, an ISP, a flash (e.g., an LED or xenon lamp), etc.

The power management module 895 may manage power of, for example, the electronic device 801. The power management module 895 may include a power management integrated circuit (PMIC), a charger IC, or a battery or fuel gauge. The battery 896 may include, for example, a rechargeable battery or a solar battery.

The indicator 897 may display a specific status of the electronic device 801 or a part thereof (e.g., the processor 810), e.g., a boot-up status, a message status, a charging status, etc. The motor 898 may convert an electrical signal into mechanical vibration, and may generate a vibration effect, a haptic effect, etc.

Each of the components described in this document may be composed of one or more components, and the name of the corresponding component may be changed according to the type of the electronic device. According to various embodiments, as to an electronic device (e.g., the electronic device 801), some components thereof may be omitted, additional components may be further included therein, or some of the components may perform the functions of the corresponding components before combination in the same manner while being combined into one entity.

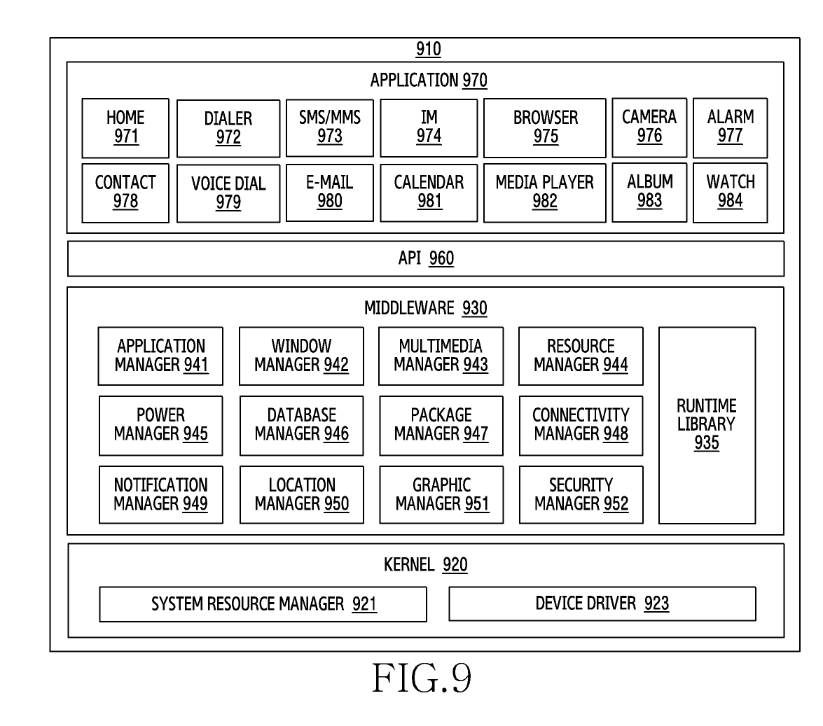

FIG. 9 is a block diagram illustrating a program module according to various embodiments of the disclosure. According to one embodiment, a program module 910 (e.g., program 240) may include an OS for controlling resources related to the electronic device (e.g., the electronic device 201) or various applications (e.g., the application programs 247) running on the OS. The OS may include, for example, Android™, iOS™, Windows™, Symbian™, Tizen™, Bada™, etc.

Referring to FIG. 9, the program module 910 may include a kernel 920 (e.g., the kernel 241), a middleware 930 (e.g., the middleware 243), an API 960 (e.g., the API 245), or applications 970 (e.g., the application program 247). At least part of the program module 910 may be preloaded on the electronic device or downloaded from a server (e.g., the electronic device 202 or 204, server 206, etc.).

The kernel 920 may include a system resource manager 921 and/or a device driver 923. The system resource manager 921 may perform a system resource control, allocation, and recall. According to one embodiment, the system resource manager 921 may include a process management unit, a memory management unit, or a file system management unit. The device driver 923 may include, for example, a display driver, a camera driver, a BT driver, a shared memory driver, a USB driver, a keypad driver, a Wi-Fi driver, an audio driver, a touch sensor driver, a pressure sensor driver, or an inter-process communication (IPC) driver.

The middleware 930 may provide a function required in common by the applications 970, or may provide various functions to the applications 970 through the API 960 so that the applications 970 may use limited system resources within the electronic device. According to one embodiment, the middleware 930 may include at least one of a runtime library 935, an application manager 941, a window manager 942, a multimedia manager 943, a resource manager 944, a power manager 945, a database (DB) manager 946, a package manager 947, a connectivity manager 948, a notification manager 949, a location manager 950, a graphic manager 951, a security manager 952, and other functions such as an audio manager.

The runtime library 935 may include, for example, a library module used by a complier to add a new function through a programming language while the applications 970 are executed. The runtime library 935 may perform input/output management, memory management, or arithmetic function processing. The application manager 941 may manage, for example, the life cycle of the applications 970. According to one embodiment, the application manager 941 may transmit a biometric information request signal to the security manager 952 based on a content request of the applications 970. The application manager 941 may provide content information provided from the DB manager 946 to the applications 970. The window manager 942 may manage GUI resources used on the screen. The multimedia manager 943 may identify a format required for reproducing media files and may perform encoding or decoding of a media file by using a codec suitable for the corresponding format. The resource manager 944 may manage a source code or a space of a memory. The power manager 945 may manage, for example, battery capacity or power, and may determine or provide power information that is necessary for the operation of an electronic device. According to one embodiment, the power manager 945 may operate together with a basic input/output system (BIOS). The DB manager 946 may generate, retrieve, or change a DB to be used by the applications 970. According to one embodiment, the DB manager 946 may retrieve a DB to detect contents matched to biometric information provided from the security manager 952. The package manager 947 may manage an installation or an update of an application distributed in a form of a package file. The connectivity manager 948 may manage, for example, a wireless connection. The notification manager 949 may provide an event such as an arrival message, an appointment, a proximity alarm or the like to a user. The location manager 950 may manage location information of the electronic device. The graphic manager 951 may manage a graphic effect provided to the user or a user interface related to the graphic effect. The security manager 952 may provide a system security or a user authentication.

According to one embodiment, the middleware 930 may include a telephony manager for managing a voice of the electronic device or a video call function or a middleware module capable of configuring a combination of the functions of the above-described components. According to one embodiment, the middleware 930 may provide modules specialized according to types of OSs. The middleware 930 may dynamically delete some existing components or add new components. The API 960 may be a set of API programming functions, and may be provided with a different configuration according to an OS. For example, in Android or iOS, a single API set may be provided for each platform. In Tizen, two or more API sets may be provided for each platform.

The applications 970 may include applications, e.g., home 971, dialer 972, SMS/multimedia messaging service (MMS) 973, instant message (IM) 974, browser 975, camera 976, alarm 977, contact 978, voice dial 979, email 980, calendar 981, media player 982, album 983, watch 984, health care (e.g., an application for measuring amount of exercise, blood sugar level, etc.), and environment information (e.g., an application for providing atmospheric pressure, humidity, temperature, etc.). According to one embodiment, the applications 970 may include an information exchange application for supporting information exchange between an electronic device and an external electronic device. According to one embodiment, the applications 970 may include an application providing a user authentication service. The application providing the user authentication service may include applications that need to perform user authentication to execute a function requested by a user, for example, an application providing a lock function or an application for providing a payment function. At least some of the program modules 910 may be implemented (e.g., executed) in software, firmware, hardware (e.g., the processor 210), or a combination of at least two of the same, and may include modules, programs, routines, instruction sets or processes for performing one or more functions.

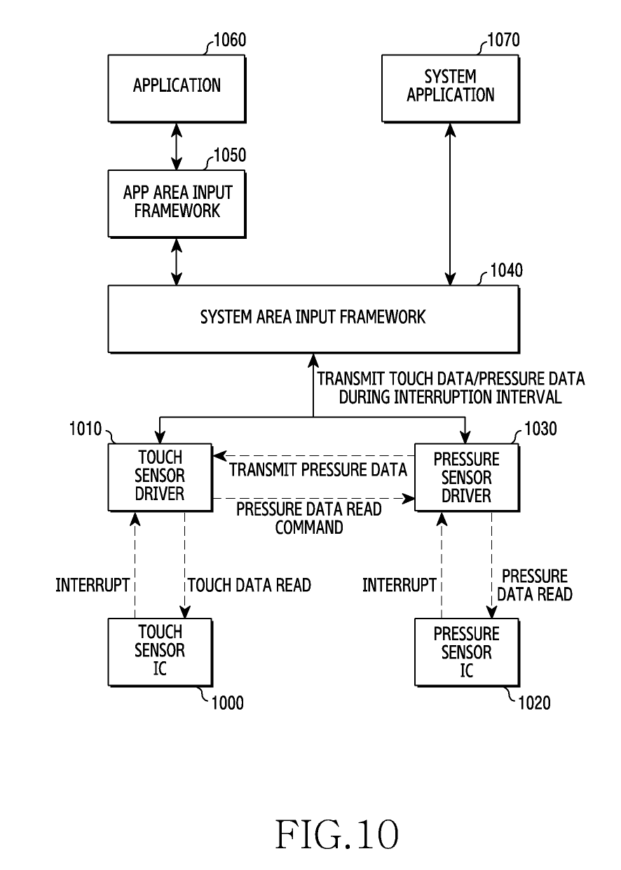

FIG. 10 is a block diagram illustrating a sensor IC and a program module representing a transmission path of touch data and pressure data according to various embodiments of the disclosure. The program module of FIG. 10 may be a part of the program module 910 illustrated in FIG. 9. A touch sensor IC 1000 and a pressure sensor IC 1020 of FIG. 10 may be the touch sensor IC 320 and the pressure sensor IC 340 illustrated in FIG. 3.

The touch sensor IC 1000 may detect a user's touch input position on a display based on transmission/reception signals with a touch sensor (e.g., touch sensor 310). The touch sensor IC 1000 may determine the touch input position and may transmit an interruption signal indicating that a touch operation has been performed to a touch sensor driver 1010. When it is determined that the touch operation has been performed based on the interruption signal of the touch sensor IC 1000, the touch sensor driver 1010 may obtain (or read) touch data from the touch sensor IC 1000 to identify a coordinate value for the touch input. The touch sensor driver 1010 may transmit the identified coordinate value for the touch input to a system area input framework 1040.

The pressure sensor IC 1020 may detect the intensity (pressure) of a touch input of a user based on the transmission/reception signals with the pressure sensor (e.g., pressure sensor 330). The pressure sensor IC 1020 may measure the detected intensity (pressure) of the touch input and may transmit the interruption signal indicating that the pressure operation has been performed to the pressure sensor driver 1030. The pressure sensor driver 1030 may obtain pressure data from the pressure sensor IC 1020 and may transmit a position where the pressure operation has been performed and a measured input intensity value to the system area input framework 1040.

The system area input framework 1040 may receive data including a coordinate value for the touch input from the touch sensor driver 1010, and may receive data including a node where the pressure operation has been performed and an input intensity value from the pressure sensor driver 1030. The data received at the system area input framework 1040 may require a synchronization process to convert the data into pair data composed of touch and pressure for each time point of transmission.

For the synchronization of the data obtained through the touch sensor and the pressure sensor, the touch sensor driver 1010 and/or the pressure sensor driver 1030 may pair a data value obtained from the pressure sensor IC 1020 and a data value obtained from the touch sensor IC 1000 at the time of occurrence of the interruption of the touch sensor IC 1000, and may transmit the paired data value to the system area input framework 1040. For example, when the interruption signal for the user input is received from the touch sensor IC 1000, the touch sensor driver 1010 may transmit a command to read touch data from the touch sensor IC 1000 and read pressure currently detected from the pressure sensor driver 1030. The pressure sensor driver 1030 may ignore the interruption signal received from the pressure sensor IC 1020, may read the pressure data currently detected through the pressure sensor from the pressure sensor IC 1020 according to an input data read command of the touch sensor driver 1010, and may transmit the read pressure data to the touch sensor driver 1010. The touch sensor driver 1010 may pair the touch data obtained from the touch sensor IC 1000 and the pressure data obtained from the pressure sensor driver 1030 and may transmit the paired data to the system area input framework 1040. According to another embodiment, in the case of an underwater environment, since the input of the touch sensor may be meaningless, the touch sensor driver 1010 and/or the pressure sensor driver 1030 may pair the touch data and the pressure data based on the interruption generated from the pressure sensor IC 1020 when the user pressure is detected through the pressure sensor, and may transmit the paired data to the system area input framework 1040.

When a system key such as a volume key, a back key, or a home key is provided as a software key, a screen layout (e.g., arrangement position or display position) of the above-described system key may be determined by fixed data (e.g., fixed coordinate value) provided by a manufacturer, and the corresponding fixed data may be applied to the system area input framework 1040. Alternatively, the screen layout of the system key in a third party application may be separately provided according to the characteristics of the application. In this case, the screen layout of the system key of the third party application may replace a default screen layout of the manufacturer while the third party application is executed and may be switched back to the default screen layout of the manufacturer when the third party application is terminated. Thus, when an application currently operating in a foreground has a screen layout of its own system key, the corresponding data may be applied to the system area input framework 1040.

The system area input framework 1040 may compare the touch coordinate value and the pressure intensity value transmitted from the touch sensor driver 1010 and/or the pressure sensor driver 1030 with the screen layout of the currently applied system key, and thereby may confirm whether the touch coordinate value and the pressure intensity value correspond to the key of the system area. When the touch coordinate value corresponds to the key of the system area and the pressure intensity value is within an effective range capable of triggering an operation corresponding to the key of the system area, the system area input framework 1040 may send the touch coordinate value and the pressure intensity value to a system application 1070 and may terminate processing of the transmitted touch coordinate value and pressure intensity value. The system application 1070 may perform the operation corresponding to the key of the system area based on the touch coordinate value and the pressure intensity value. When the touch coordinate value does not correspond to the key of the system area or when the pressure intensity value is outside the effective range capable of triggering the operation corresponding to the key of the system area, the system area input framework 1040 may transmit the touch coordinate value and the pressure intensity value to an application area input framework 1050.

The application area input framework 1050 may identify whether the received touch coordinate value and pressure intensity value are meaningful events. For example, the application area input framework 1050 may identify a pattern of the touch coordinate values and pressure intensity values input for a predetermined period of time, and may determine whether the identified pattern matches predefined event criteria such as dragging, long touch, or moving. When the identified pattern matches the predefined event criterion, the application area input framework 1050 may determine the received touch coordinate value and pressure intensity value as a final event and may transmit the determined values to an application 1060.

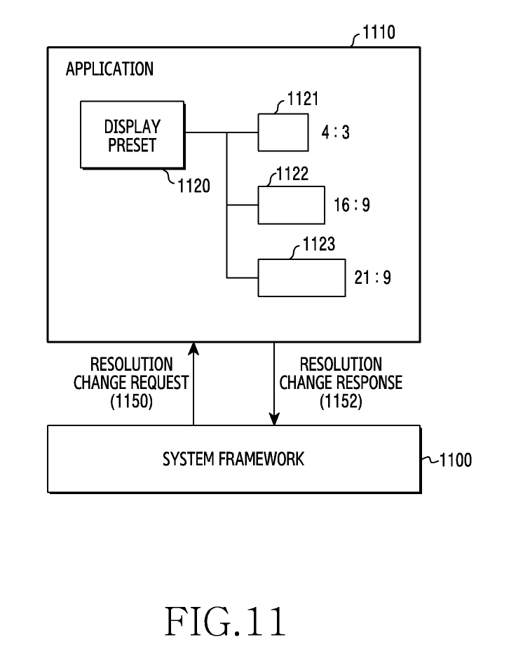

FIG. 11 is a block diagram illustrating a program module for resolution change in an electronic device according to various embodiments of the disclosure. The program module of FIG. 11 may be a part of the program module 910 illustrated in FIG. 9.

According to various embodiments, a system framework 1100 may perform a function for adjusting the resolution of an application being displayed when an abnormal operation of a pressure sensor is detected. When the abnormal operation of the pressure sensor is detected while an application execution screen is displayed in a first region, the system framework 1100 may transmit a signal 1150 requesting a change in the resolution to the application 1110. The resolution change request signal 1150 may include information indicating the position and size of the first region. The system framework 1100 may receive a resolution change response signal 1152 from the application 1110 in response to the resolution change request signal. According to one embodiment, the resolution change response signal may include at least one of changed resolution information and at least one application execution image corresponding to the changed resolution. The system framework 1100 may control the application execution screen not to be displayed in the first region by adjusting the display resolution of the application based on the resolution change response signal. The system framework 1100 may control an object for executing a function associated with a pressure input to the first region to be displayed. According to one embodiment, the resolution change response signal may include indicating that a proper resolution does not exist. The system framework 1100 may control a function corresponding to the pressure input to the first region to be executed by a combination of touch inputs (e.g., double touch or long touch) without changing the display resolution of the currently displayed application.

When the resolution change request signal 1150 is received from the system framework 1100, the application 1110 may retrieve a display preset 1120 configured in advance with respect to the currently displayed application. The display preset 1120 may be composed of a plurality of display image sets having different resolutions. For example, the display preset 1120 may include a first image set 1121 with an aspect ratio of 4:3, a second image set 1122 with an aspect ratio of 16:9, and a third image set 1123 with an aspect ratio of 21:9. The application 1110 may select a resolution to be changed based on at least one of the position and size of the first region included in the resolution change request signal 1150. The application 1110 may provide the resolution change response signal including at least one of selected resolution information and at least one application execution image corresponding to the selected resolution, to the system framework 1100.

According to various embodiments, an electronic device includes a housing including a first plate and a second plate facing in a direction opposite of the first plate, a touch screen display disposed in the housing and including a first surface exposed through a part of the first plate and a second surface facing a direction of the second plate, a pressure sensing circuit attached to the second surface via an adhesive layer, disposed between the first plate and the second plate, and configured to detect a pressure on a first region of the touch screen display by an external force, a wireless communication circuit disposed in the housing, a memory disposed in the housing, and at least one processor disposed in the housing and electrically connected with the touch screen display, the pressure sensing circuit, the wireless communication circuit, and the memory, wherein the memory stores instructions that, when executed by the at least one processor, cause the at least one processor to detect the pressure on the first region of the touch screen display using the pressure sensing circuit and to perform an operation associated with the electronic device in response to the detected pressure, when an abnormal operation of the pressure sensing circuit is not detected, and to detect a touch on the first region using the touch screen display and to perform the operation associated with the electronic device in response to the detected touch, when the abnormal operation of the pressure sensing circuit is detected.

According to various embodiments, the instructions, when executed by the at least one processor, may cause the at least one processor to control to display a first user interface in the first region of the touch screen display when the abnormal operation of the pressure sensing circuit is not detected, and to control to display a second user interface in the first region of the touch screen display when the abnormal operation of the pressure sensing circuit is detected. The second user interface may be different from the first user interface.

According to various embodiments, the second user interface may include a symbol indicating a home button.

According to various embodiments, the second user interface may include a first object corresponding to the operation associated with the electronic device.

According to various embodiments, each of the first user interface and the second user interface may include a second object.

According to various embodiments, the instructions, when executed by the at least one processor, may cause the at least one processor to control to display the second object in the first region of the touch screen display when the abnormal operation of the pressure sensing circuit is not detected, and to control to display the first object in the first region of the touch screen display and to display the second object in another region of the display when the abnormal operation of the pressure sensing circuit is detected.

According to various embodiments, a display resolution of the second object included in the first user interface may be different from a display resolution of the second object included in the second user interface.

According to various embodiments, the instructions, when executed by the at least one processor, may cause the at least one processor to detect the abnormal operation of the pressure sensing circuit based on a parasitic capacitance between the touch screen display and the pressure sensing circuit.

According to various embodiments, the instructions, when executed by the at least one processor, may cause the at least one processor to control to detect a second touch on the touch screen display and to control to detect the abnormal operation of the pressure sensing circuit based on whether a pressure due to the detected second touch is detected through the pressure sensing circuit.

According to various embodiments, the instructions, when executed by the at least one processor, may cause the at least one processor to detect the abnormal operation of the pressure sensing circuit when the pressure due to the detected touch is not detected through the pressure sensing circuit, and to detect the abnormal operation of the pressure sensing circuit based on whether the detected pressure is within an effective range when the pressure due to the detected touch is detected through the pressure sensing circuit.

According to various embodiments, the pressure sensing circuit may detect the pressure based on at least one of a change amount of a capacitance formed between a first electrode and a second electrode, a change amount of a current induced in an inductor, a change amount of resistance of a conductor, a change amount of a current of a piezo material, or a change amount of a voltage of the piezo material.

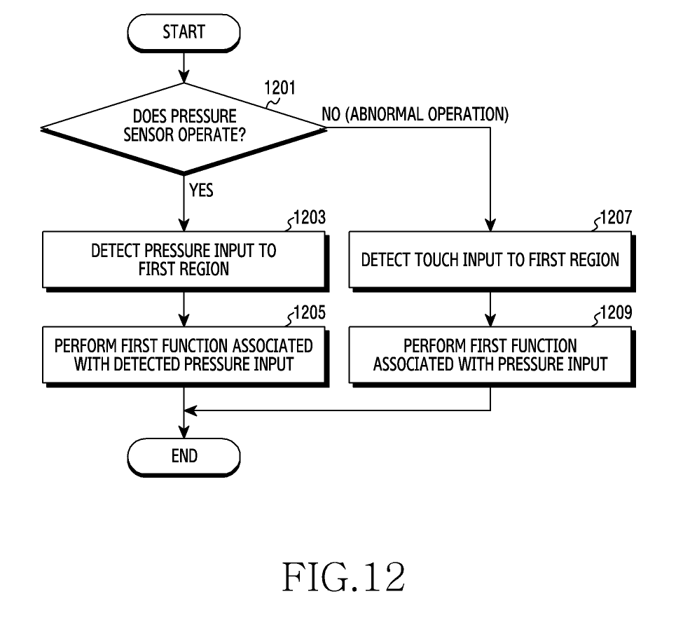

FIG. 12 illustrates an operational procedure according to whether a pressure sensor operates normally in an electronic device according to various embodiments of the disclosure. In the following embodiments, each operation may be performed sequentially, but it is not necessarily performed sequentially. For example, the order of each operation may be changed, and at least two operations may be performed in parallel. Here, an electronic device may be the electronic device 201 of FIG. 2.

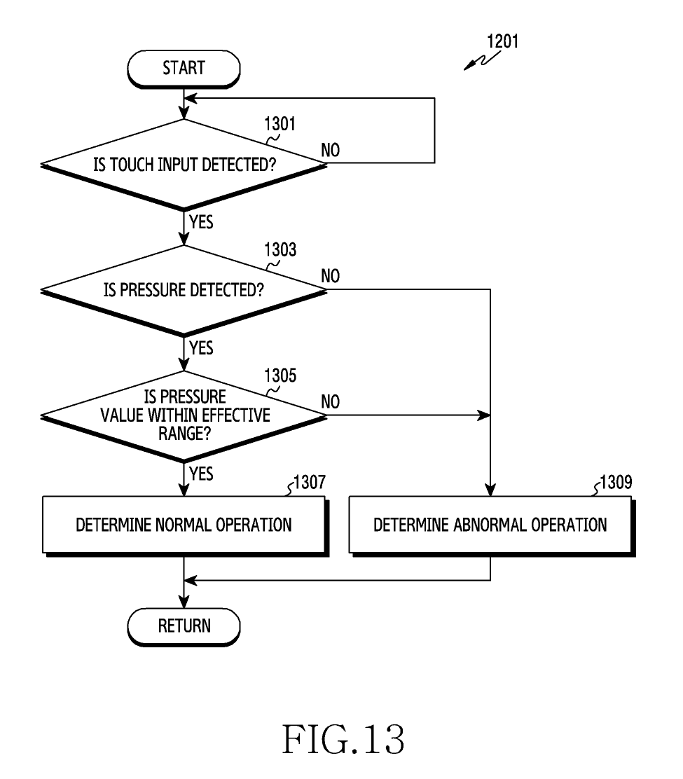

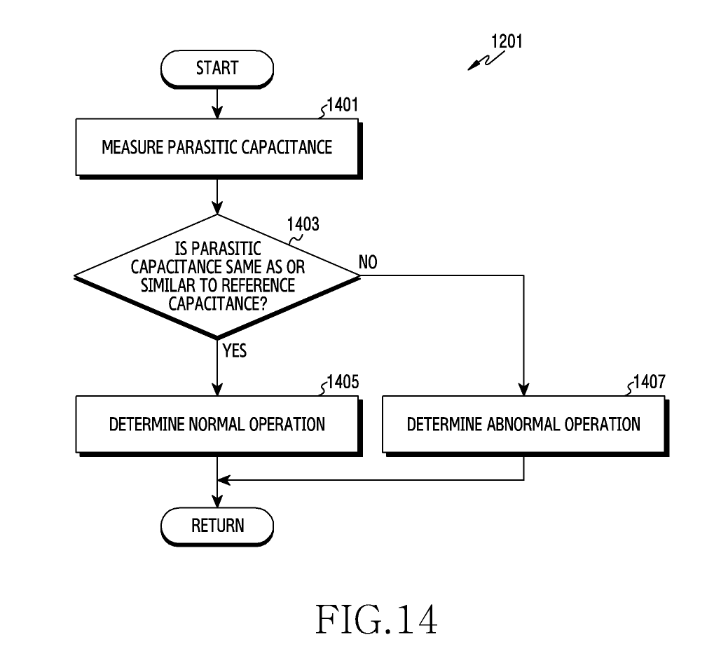

Referring to FIG. 12, in operation 1201, an electronic device may determine whether a pressure sensor operates normally. According to one embodiment, the processor 220 of the electronic device may determine whether a pressure sensor 282 operates normally based on whether a pressure due to a touch input is detected. According to one embodiment, when the pressure sensor 282 included in the electronic device is driven in a capacitive manner, the processor 220 of the electronic device may detect whether the pressure sensor 282 operates normally based on a parasitic capacitance value associated with the pressure sensor 282. In FIGS. 13 and 14, the operation of determining whether the pressure sensor operates normally will be described in more detail.

When it is determined that the pressure sensor operates normally, a pressure input to a first region may be detected in operation 1203. According to one embodiment, the processor 220 of the electronic device may detect the pressure input to the first region of the display 260 through the pressure sensor 282. The first region may be a region in which an operation, function or control command of the electronic device associated with the pressure input is mapped. The operation, function, or control command of the electronic device associated with the pressure input mapped to the first region may be fixed or variable. For example, a first function (e.g., pressure input-home screen display) associated with the pressure input may be fixedly mapped to the first region. As another example, the function associated with the pressure input mapped to the first region may be changed based on the operating state of the electronic device (e.g., AOD mode state, home screen display state, the presence/absence of application execution, the currently executed application, etc.). For example, when the electronic device operates in the AOD mode, “pressure input-home screen display” may be mapped to the first region, and when the electronic device displays a home screen, “pressure input-first application execution” may be mapped to the first region. According to one embodiment, the first region may be a region associated with the pressure sensor 282 in the entire region of the display 260. For example, when the pressure sensor 282 is attached to at least a partial region (e.g., P1 region 120) of the entire region of the touch screen display 101, the first region may be at least a partial region of the P1 region 120 and a region adjacent to the P1 region 120. As another example, when the pressure sensor 282 is attached to a region (e.g., P2 region 122) corresponding to the entire region of the touch screen display 101, the first region may be at least a partial region of the P2 region 122.

In operation 1205, the electronic device may perform a first function associated with the detected pressure input. According to one embodiment, the processor 220 may perform the first function associated with the pressure input to the first region in response to the detection of the pressure input to the first region. For example, the processor 220 of the electronic device may confirm that “pressure input-home screen display” is mapped to the first region, and may control the home screen to be displayed on the display 260 in response to the detection of the pressure input to the first region.

When it is determined that the pressure sensor operates abnormally, the electronic device may detect a touch input to the first region in operation 1207. According to one embodiment, the processor 220 of the electronic device may detect the touch input to the first region of the display 260 through the touch sensor 281. The first region may be a region in which an operation, function, or control command of the electronic device associated with the pressure input is mapped.

In operation 1209, the electronic device may perform the first function associated with the pressure input in response to the detection of the touch input. According to one embodiment, the processor 220 of the electronic device may perform the first function associated with the pressure input to the first region in response to the detection of the touch input to the first region. For example, the processor 220 of the electronic device may confirm that “pressure input-home screen display” is mapped to the first region, and may control the home screen to be displayed on the display 260 in response to the detection of the touch input to the first region.

FIG. 13 illustrates an operational procedure for detecting whether a pressure sensor operates normally in an electronic device according to various embodiments of the disclosure. Hereinafter, the operation of determining whether the pressure sensor operates normally in operation 1201 of FIG. 12 will be described. In the following embodiments, each operation may be performed sequentially, but it is not necessarily performed sequentially. For example, the order of each operation may be changed, and at least two operations may be performed in parallel. Here, an electronic device may be the electronic device 201 of FIG. 2.

Referring to FIG. 13, in operation 1301, an electronic device may determine whether a touch input is detected. According to one embodiment, the processor 220 of the electronic device may determine whether a user's touch input to the display 260 is detected through the touch sensor 281.

When the touch input is detected, the electronic device may determine whether a pressure is detected in operation 1303. According to one embodiment, the processor 220 of the electronic device may determine whether a pressure (intensity) of the touch input is detected through the pressure sensor 282 when the touch input is detected through the touch sensor 281. The detected pressure value (or pressure data) may be different values depending on the type of the pressure sensor. For example, when the pressure sensor 282 is a capacitive pressure sensor, the pressure value may be a value indicating a capacitance change amount. When the pressure sensor 282 is an inductive pressure sensor, the pressure value may be a value indicating a current change amount. When the pressure sensor 282 is a strain gauge pressure sensor, the pressure value may be a value indicating a resistance change amount. When the pressure sensor 282 is a piezoelectric pressure sensor, the pressure value may be a value indicating a current change amount or a voltage change amount.

When the pressure is not detected, the electronic device may determine that the pressure sensor operates abnormally in operation 1309. According to one embodiment, when a signal indicating that the touch input is detected is received from the touch sensor 281 but the pressure value corresponding to a time point when the touch input is detected is not received from the pressure sensor 282, the processor 220 may determine that the pressure sensor 282 operates abnormally. According to one embodiment, when the signal indicating that the touch input is detected is received from the touch sensor 281 and a significantly small pressure value (e.g., a pressure value substantially close to zero) corresponding to a time point when the touch input is detected from the pressure sensor 282, the processor 220 may determine that the pressure sensor 282 operates abnormally.

In operation 1305, when the pressure is detected, the electronic device may determine whether the pressure value is within an effective range. According to one embodiment, when the signal indicating that the touch input is detected is received from the touch sensor 281 and the pressure value corresponding to the time point when the touch input is detected is received from the pressure sensor 282, the processor 220 of the electronic device may determine whether the received pressure value is larger than 0.

In operation 1307, when the pressure value is within the effective range, the electronic device may determine that the pressure sensor 282 operates normally. According to one embodiment, when the pressure value detected through the pressure sensor 282 is larger than 0, the processor 220 of the electronic device may determine that the pressure sensor 282 operates normally.

In operation 1309, when the pressure value is outside the effective range, the electronic device may determine that the pressure sensor 282 operates abnormally. According to one embodiment, when the pressure value detected through the pressure sensor 282 is equal to or smaller than 0, the processor 220 of the electronic device may determine that the pressure sensor 282 operates abnormally.

FIG. 14 illustrates an operational procedure for detecting whether a pressure sensor operates normally in an electronic device according to various embodiments of the disclosure. Hereinafter, the operation of determining whether the pressure sensor driven in the capacitance manner operates normally in operation 1201 of FIG. 12 will be described in detail. In the following embodiments, each operation may be performed sequentially, but it is not necessarily performed sequentially. For example, the order of each operation may be changed, and at least two operations may be performed in parallel. Here, an electronic device may be the electronic device 201 of FIG. 2.

Referring to FIG. 14, in operation 1401, an electronic device may measure a parasitic capacitance. For example, the processor 220 of the electronic device may acquire a parasitic capacitance formed between the display 260 and the pressure sensor 282 through a pressure sensor IC.

In operation 1403, the electronic device may determine whether the measured parasitic capacitance is the same as a predetermined reference capacitance or is similar thereto within a reference range. The reference capacitance may be set as a value obtained by measuring a parasitic capacitance formed between the pressure sensor 282 and the display 260 or between the pressure sensor 282 and another component in a state in which the pressure sensor 282 is normally attached to the display 260 or another component.

When the parasitic capacitance is the same as the predetermined reference capacitance or is similar thereto within the reference range, the electronic device may determine that the pressure sensor operates normally in operation 1405. According to one embodiment, when the parasitic capacitance is the same as the predetermined reference capacitance, the processor 220 of the electronic device may determine that the pressure sensor 282 operates normally, assuming that the pressure sensor 282 is normally attached to the display 260 or another component. According to one embodiment, when the parasitic capacitance is not the same as the reference capacitance but a difference between the parasitic capacitance and the reference capacitance is equal to or smaller than a first threshold value, the processor 220 of the electronic device may determine that the parasitic capacitance and the reference capacitance are similar to each other within the reference range, and may determine that the pressure sensor 282 operates normally.

In operation 1407, when the parasitic capacitance and the predetermined reference capacitance are different from each other, the electronic device may determine that the pressure sensor operates abnormally. According to one embodiment, when the parasitic capacitance is not the same as the predetermined reference capacitance and the difference therebetween is larger than the first threshold value, the processor 220 of the electronic device may determine that the pressure sensor 282 operates abnormally, assuming that the pressure sensor 282 is not normally attached to the display 260 or another component.

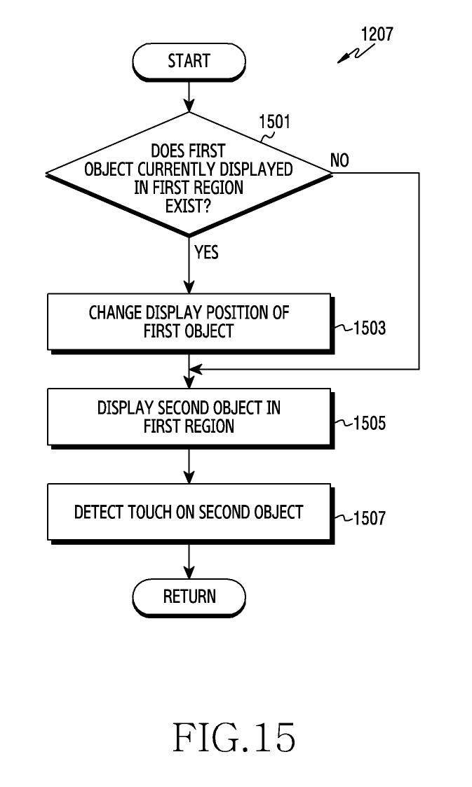

FIG. 15 illustrates an operational procedure for detecting a touch input for triggering an event corresponding to a pressure input in an electronic device according to various embodiments of the disclosure.

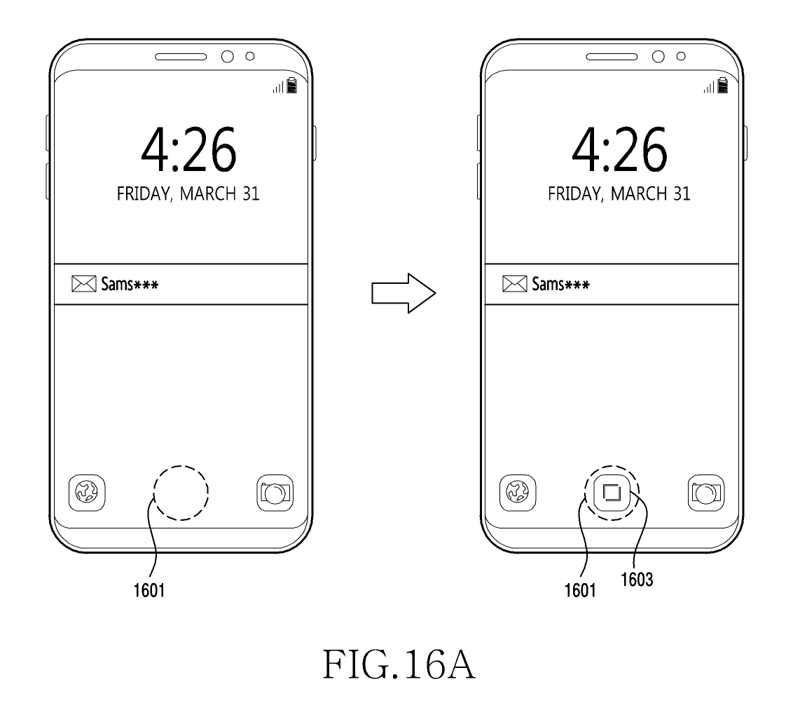

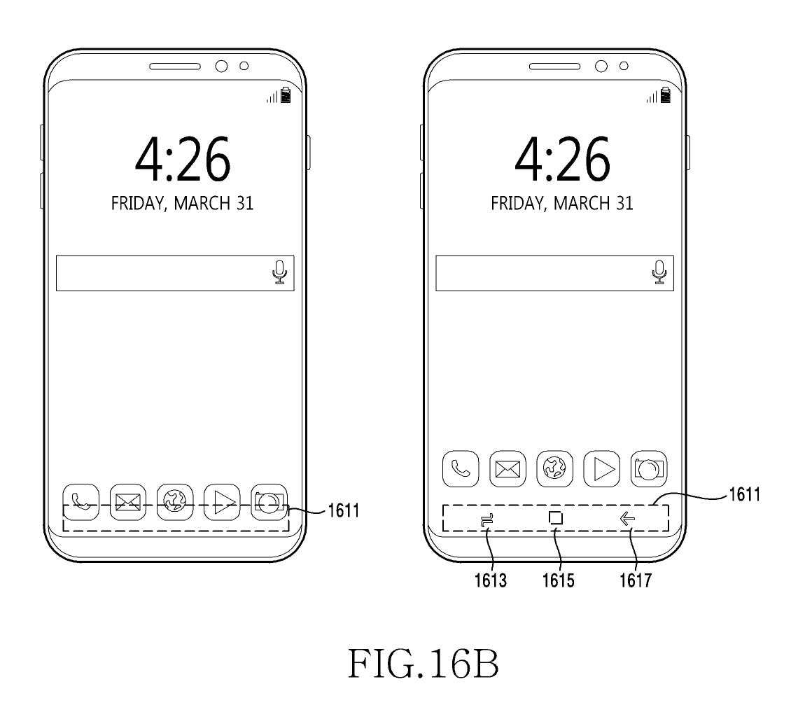

FIGS. 16A and 16B illustrate screen configurations changed when an abnormal operation of a pressure sensor is detected in an electronic device according to various embodiments of the disclosure. Hereinafter, the operation of detecting the touch input to the first region when the pressure sensor operates abnormally in operation 1203 of FIG. 12 will be described in detail. In the following embodiments, each operation may be performed sequentially, but it is not necessarily performed sequentially. For example, the order of each operation may be changed, and at least two operations may be performed in parallel. Here, an electronic device may be the electronic device 201 of FIG. 2.

Referring to FIGS. 15, 16A, and 16B, in operation in 1501, an electronic device may determine whether a first object which is currently displayed in the first region exists. According to one embodiment, when an abnormal operation of the pressure sensor is detected, the processor 220 of the electronic device may determine whether the first object associated with a touch input is displayed in the first region where a function associated with the pressure input is mapped.

In operation 1505, when the first object which is currently displayed in the first region does not exist, the electronic device may display a second object in the first region. For example, as shown in FIG. 16A, when the object that is currently displayed in the first region 1601 does not exist, the processor 220 of the electronic device may display a home button object 1603 in the first region 1601.

In operation 1503, when the first object which is currently displayed in the first region exists, the electronic device may change the display position of the first object. According to one embodiment, the processor 220 of the electronic device may change the display region of the first object from the first region of the display 260 to a second region thereof. The second region may be a region where the function associated with the pressure input is not mapped. The second region may be a region where another object associated with the touch input is not displayed. According to one embodiment, the processor 220 of the electronic device may remove the function associated with the touch input mapped to the first region while changing the display region of the first object from the first region to the second region. For example, when “pressure input-home screen display” and “touch input-first application execution” are mapped to the first region, the processor 220 may cancel the mapping of “touch input-first application execution” to the first region, and may map “touch input-first application execution” to the second region. According to one embodiment, when a plurality of first objects is displayed in the first region, the processor 220 of the electronic device may change the display regions of the plurality of first objects to the second region. According to one embodiment, when the display regions of the plurality of first objects are changed, the processor 220 of the electronic device may change the display region of at least one other third object associated with the first object.

In operation 1505, the electronic device may display a second object in the first region. According to one embodiment, the processor 220 of the electronic device may identify the function associated with the pressure input mapped to the first region, and may control the display 260 so that the second object corresponding to the identified function may be displayed in the first region. According to one embodiment, when there are a plurality of functions associated with the pressure input to the first region, the processor 220 of the electronic device may control a plurality of second objects corresponding to the plurality of functions to be displayed in the first region. For example, as illustrated in FIG. 16B, when there are a plurality of application icons which are currently displayed in a first region 1611, the processor 220 of the electronic device may move the plurality of icons to another region to display the same, and may display a recent history view object 1613, a home button object 1615, or a return object 1617 in the first area 1611.

In operation 1507, the electronic device may detect a touch on the second object. For example, the electronic device may detect a user's touch input on the second object which is displayed in the first region of the display 260.

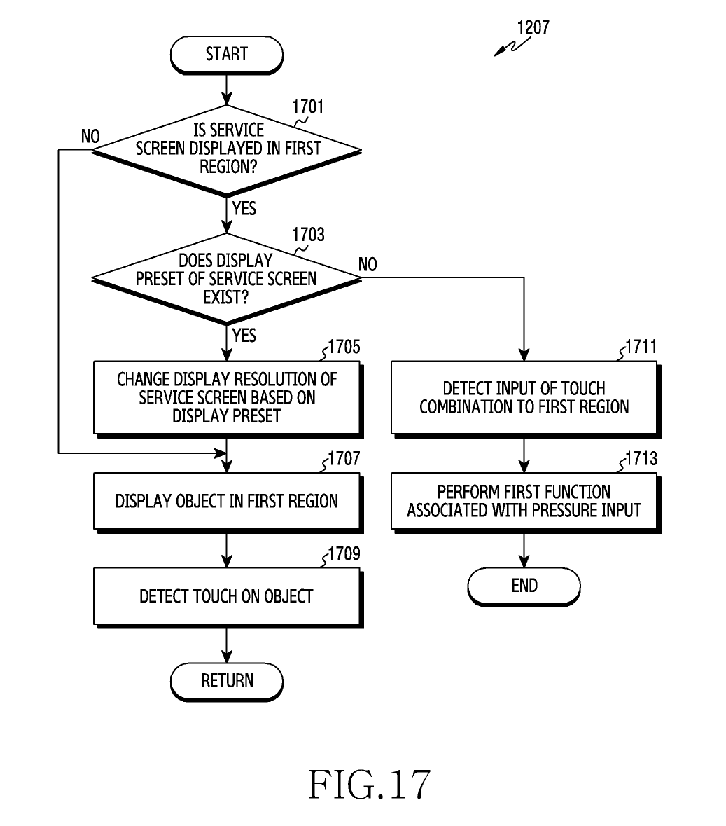

FIG. 17 illustrates an operational procedure for detecting a touch input for triggering an event corresponding to a pressure input in an electronic device according to various embodiments of the disclosure.

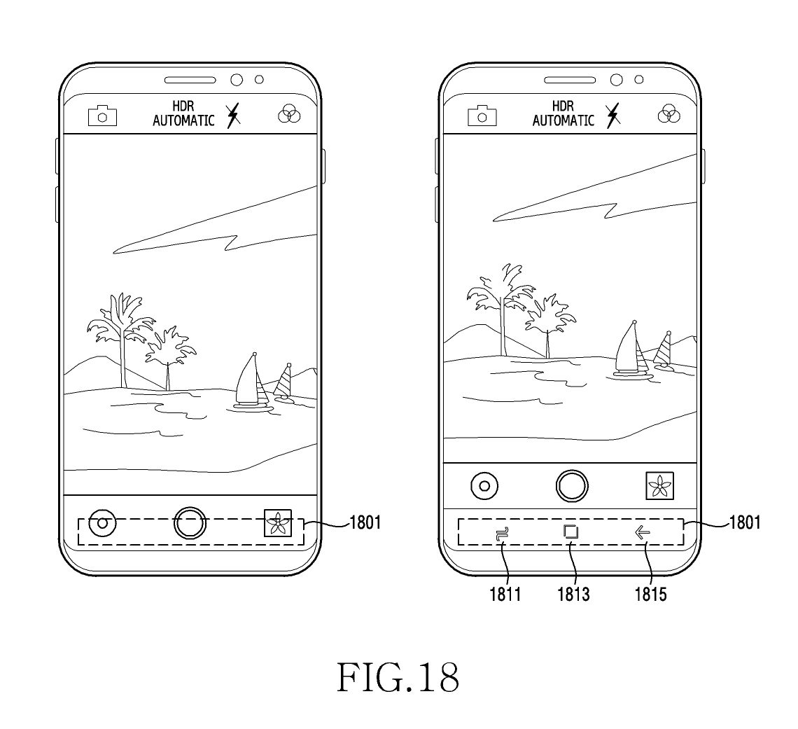

FIG. 18 illustrates a screen configuration changed when an abnormal operation of a pressure sensor is detected in an electronic device according to various embodiments of the disclosure. Hereinafter, the operation of detecting the touch input to the first region when the pressure sensor operates abnormally in operation 1203 of FIG. 12 will be described in detail. In the following embodiments, each operation may be performed sequentially, but it is not necessarily performed sequentially. For example, the order of each operation may be changed, and at least two operations may be performed in parallel. Here, an electronic device may be the electronic device 201 of FIG. 2.

Referring to FIG. 17, in operation 1701, an electronic device may determine whether a service screen is displayed in a first region. According to one embodiment, the processor 220 of the electronic device may determine whether the display region of the service screen which is currently displayed on a screen by a user input is included in the first region. The service screen may include at least one of an application execution screen, an AOD screen, a home screen, and an operation execution screen due to a user input.

In operation 1707, when the service screen is not displayed in the first region, the electronic device may display an object in the first region. Operation 1707 will be hereinafter described in detail.

In operation 1703, when the service screen is displayed in the first region, the electronic device may determine whether a display preset exists. The display preset may include a plurality of display image sets having different resolutions. For example, the display preset may include a first image set with an aspect ratio of 4:3, a second image set with an aspect ratio of 16:9, and a third image set with an aspect ratio of 21:9.

In operation 1705, when there is a display preset associated with the service screen, the electronic device may change the display resolution of the service screen based on the display preset. According to one embodiment, the processor 220 of the electronic device may determine a resolution to be changed based on the position and size of the first region, and may select a display image set corresponding to the determined resolution within the display preset. The processor 220 may control the service screen to be displayed on the display 260 based on the selected display image set. The processor 220 may control the service image not to be displayed in the first region of the display 260 by changing the display resolution of the service screen.

In operation 1707, the electronic device may display the object in the first region. According to one embodiment, the processor 220 of the electronic device may control at least one object for executing the function associated with the pressure input to the first region to be displayed in the first region of the display 260. As illustrated in FIG. 18, when a camera application execution screen is displayed in the entire region of the display 260, the processor 220 may change the display resolution of the camera application execution screen to prevent the camera application execution screen from being displayed in the first region 1801, and may control a recent history view object 1811, a home button object 1813, and a return object 1815 to be displayed in the first region 1801.

In operation 1709, the electronic device may detect a touch on the object. According to one embodiment, the processor 220 of the electronic device may detect a touch input to the object that is displayed in the first region of the display 260 through the touch sensor 281.

In operation in 1711, when the display preset associated with the service screen does not exist, the electronic device may detect an input in the form of a touch combination with respect to the first region. The input in the form of the touch combination may refer to an input in the form of a combination of the touch input and additional elements (e.g., touch frequency, touch time, etc.) such as a double touch input, a long touch input, etc.

In operation 1713, the electronic device may perform a first function associated with the pressure input. According to one embodiment, the processor 220 of the electronic device may perform the first function associated with the pressure input to the first region in response to the detection of the input in the form of a touch combination on the first region. For example, when the pressure sensor 282 operates abnormally in a state in which “pressure input-home screen display” is mapped to the first region, the processor 220 of the electronic device may perform a display function on the home screen in response to the detection of a double touch input to the first region.

According to various embodiments, an operating method of an electronic device may include detecting an abnormal operation of a pressure sensing circuit; performing an operation associated with the electronic device in response to a pressure to a first region of a display using the pressure sensing circuit when the abnormal operation of the pressure sensing circuit is not detected; and performing the operation associated with the electronic device in response to a touch on the first region using the touch screen display when the abnormal operation of the pressure sensing circuit is detected.

According to various embodiments, the operating method may further include displaying a first user interface in the first region of the touch screen display when the abnormal operation of the pressure sensing circuit is not detected; and displaying a second user interface in the first region of the touch screen display when the abnormal operation of the pressure sensing circuit is detected. The second user interface may be different from the first user interface.

According to various embodiments, the second user interface may include a symbol indicating a home button.

According to various embodiments, the second user interface may include a first object corresponding to the operation associated with the electronic device.

According to various embodiments, each of the first user interface and the second user interface may include a second object, the displaying of the first user interface may include displaying the second object in the first region of the touch screen display, and the displaying of the second user interface may include displaying the first object in the first region of the touch screen display and displaying the second object in another region of the touch screen display.

According to various embodiments, a display resolution of the second object included in the first user interface may be different from a display resolution of the second object included in the second user interface.

According to various embodiments, the detecting of the abnormal operation of the pressure sensing circuit may include detecting the abnormal operation of the pressure sensing circuit based on a parasitic capacitance between the touch screen display and the pressure sensing circuit.

According to various embodiments, the detecting of the abnormal operation of the pressure sensing circuit may include detecting a second touch on the touch screen display; and detecting the abnormal operation of the pressure sensing circuit based on whether a pressure due to the detected second touch is detected through the pressure sensing circuit.

According to various embodiments, the operating method may further include detecting the abnormal operation of the pressure sensing circuit when the pressure due to the detected touch is not detected through the pressure sensing circuit; and detecting, when the pressure due to the detected touch is detected through the pressure sensing circuit, the abnormal operation of the pressure sensing circuit based on whether the detected pressure is within an effective range.

According to various embodiments, the pressure may be detected based on at least one of a change amount of a capacitance formed between a first electrode and a second electrode, a change amount of a current induced in an inductor, a change amount of resistance of a conductor, a change amount of a current of a piezo material, or a change amount of a voltage of the piezo material.

The electronic device and the operating method thereof according to various embodiments may provide services corresponding to the pressure input using a touch input, when abnormal operation of the pressure sensor is detected in the electronic device, thereby minimizing user inconvenience due to the abnormal operation of the pressure sensor.

The term “module” used herein may refer to a unit including one of hardware, software, or firmware, or a combination of two or more of them. The “module” may be interchangeably used with the terms “unit,” “logic,” “logical block,” “component” or “circuit”. The “module” may be a minimum unit of an integrally configured component or a part thereof. The “module” may be a minimum unit for performing one or more functions or a part thereof. The “module” may be implemented mechanically or electronically. For example, the “module” may include an application-specific IC (ASIC) chip, a field-programmable gate array (FPGA), and a programmable-logic device for performing some operations, which are known or will be developed.

At least part of a device (for example, modules or functions thereof) or a method (for example, operations) according to various embodiments, for example, may be implemented by instructions stored in a non-transitory computer-readable storage medium in the form of a program module. When the instruction is executed by a processor (for example, the processor), one or more processors may perform a function corresponding to the instruction. The non-transitory computer-readable storage medium may be, for example, a memory.

The non-transitory computer-readable recording media may include a hard disk, a floppy disk, magnetic media (for example, a magnetic tape), optical media (for example, compact disc read only memory (CD-ROM) and a DVD, magneto-optical media (for example, a floptical disk)), or a hardware device (for example, a read only memory (ROM), a random access memory (RAM), or a flash memory). Also, a program command may include not only a mechanical code such as things generated by a compiler but also a high-level language code executable on a computer using an interpreter. The above hardware device may be configured to operate via one or more software modules for performing an operation of various embodiments, and vice versa.

A module or a program module according to various embodiments may include at least one of the above elements, or a portion of the above elements may be omitted, or additional other elements may be further included. Operations performed by a module, a program module, or other elements according to various embodiments may be executed sequentially, in parallel, repeatedly, or in a heuristic method. Also, a portion of operations may be executed in different sequences, omitted, or other operations may be added.

The disclosure has been shown and described with reference to various embodiments thereof, it will be understood by a person skilled in the art that various changes in form and details may be made therein without departing from the spirit and scope of the disclosure as defined by the appended claims and their equivalents.

What is claimed is:

1. An electronic device comprising:
a housing including a first plate and a second plate facing in a direction opposite of the first plate;
a touch screen display disposed in the housing and including a first surface exposed through a part of the first plate and a second surface facing a direction of the second plate;
a pressure sensing circuit attached to the second surface via an adhesive layer, disposed between the first plate and the second plate, and configured to detect a pressure on a first region of the touch screen display by an external force;
a wireless communication circuit disposed in the housing;
a memory disposed in the housing; and
at least one processor disposed in the housing and electrically connected with the touch screen display, the pressure sensing circuit, the wireless communication circuit, and the memory;
wherein the memory stores instructions that, when executed by the at least one processor, cause the at least one processor to:
detect the pressure on the first region of the touch screen display using the pressure sensing circuit and to perform an operation associated with the electronic device in response to the detected pressure, when an abnormal operation of the pressure sensing circuit is not detected, and
detect a touch on the first region using the touch screen display and to perform the operation associated with the electronic device in response to the detected touch, when the abnormal operation of the pressure sensing circuit is detected.

2. The electronic device of claim 1,
wherein the instructions, when executed by the at least one processor, cause the at least one processor to control to:
display a first user interface in the first region of the touch screen display when the abnormal operation of the pressure sensing circuit is not detected, and
display a second user interface in the first region of the touch screen display when the abnormal operation of the pressure sensing circuit is detected, and
wherein the second user interface is different from the first user interface.

3. The electronic device of claim 2, wherein the second user interface includes a symbol indicating a home button.

4. The electronic device of claim 2, wherein the second user interface includes a first object corresponding to the operation associated with the electronic device.

5. The electronic device of claim 4,
wherein each of the first user interface and the second user interface includes a second object, and
wherein the instructions, when executed by the at least one processor, cause the at least one processor to control to:
display the second object in the first region of the touch screen display when the abnormal operation of the pressure sensing circuit is not detected, and
display the first object in the first region of the touch screen display and to display the second object in another region of the touch screen display when the abnormal operation of the pressure sensing circuit is detected.

6. The electronic device of claim 5, wherein a display resolution of the second object included in the first user interface is different from a display resolution of the second object included in the second user interface.

7. The electronic device of claim 1, wherein the instructions, when executed by the at least one processor, cause the at least one processor to detect the abnormal operation of the pressure sensing circuit based on a parasitic capacitance between the touch screen display and the pressure sensing circuit.

8. The electronic device of claim 1, wherein the instructions, when executed by the at least one processor, cause the at least one processor to:
control to detect a second touch on the touch screen display, and
detect the abnormal operation of the pressure sensing circuit based on whether a pressure due to the detected second touch is detected through the pressure sensing circuit.

9. The electronic device of claim 8, wherein the instructions, when executed by the at least one processor, cause the at least one processor to:
detect the abnormal operation of the pressure sensing circuit when the pressure due to the detected touch is not detected through the pressure sensing circuit, and
detect the abnormal operation of the pressure sensing circuit based on whether the detected pressure is within an effective range when the pressure due to the detected touch is detected through the pressure sensing circuit.

10. The electronic device of claim 8, wherein the pressure sensing circuit detects the pressure based on at least one of a change amount of a capacitance formed between a first electrode and a second electrode, a change amount of a current induced in an inductor, a change amount of resistance of a conductor, a change amount of a current of a piezo material, or a change amount of a voltage of the piezo material.

11. An operating method of an electronic device, the operating method comprising:
detecting an abnormal operation of a pressure sensing circuit;
performing an operation associated with the electronic device in response to a pressure to a first region of a display using the pressure sensing circuit when the abnormal operation of the pressure sensing circuit is not detected; and
performing the operation associated with the electronic device in response to a touch on the first region using the touch screen display when the abnormal operation of the pressure sensing circuit is detected.

12. The operating method of claim 11, further comprising:
displaying a first user interface in the first region of the touch screen display when the abnormal operation of the pressure sensing circuit is not detected; and
displaying a second user interface in the first region of the touch screen display when the abnormal operation of the pressure sensing circuit is detected,
wherein the second user interface is different from the first user interface.

13. The operating method of claim 12, wherein the second user interface includes a symbol indicating a home button.

14. The operating method of claim 12, wherein the second user interface includes a first object corresponding to the operation associated with the electronic device.

15. The operating method of claim 14,
wherein each of the first user interface and the second user interface includes a second object,
wherein the displaying of the first user interface includes displaying the second object in the first region of the touch screen display, and
wherein the displaying of the second user interface includes displaying the first object in the first region of the touch screen display and displaying the second object in another region of the touch screen display.

16. The operating method of claim 15, wherein a display resolution of the second object included in the first user interface is different from a display resolution of the second object included in the second user interface.

17. The operating method of claim 11, wherein the detecting of the abnormal operation of the pressure sensing circuit includes detecting the abnormal operation of the pressure sensing circuit based on a parasitic capacitance between the touch screen display and the pressure sensing circuit.

18. The operating method of claim 11, wherein the detecting of the abnormal operation of the pressure sensing circuit includes:
detecting a second touch on the touch screen display; and
detecting the abnormal operation of the pressure sensing circuit based on whether a pressure due to the detected second touch is detected through the pressure sensing circuit.

19. The operating method of claim 18, further comprising:
detecting the abnormal operation of the pressure sensing circuit when the pressure due to the detected touch is not detected through the pressure sensing circuit; and
detecting, when the pressure due to the detected touch is detected through the pressure sensing circuit, the abnormal operation of the pressure sensing circuit based on whether the detected pressure is within an effective range.

20. The operating method of claim 18, wherein the pressure is detected based on at least one of a change amount of a capacitance formed between a first electrode and a second electrode, a change amount of a current induced in an inductor, a change amount of resistance of a conductor, a change amount of a current of a piezo material, or a change amount of a voltage of the piezo material.
